(19) United States
(12) Patent Application Publication
(10) Pub. No.: US 2025/0221137 A1
(43) Pub. Date: Jul. 3, 2025

(54) DISPLAY APPARATUS

(71) Applicant: LG Display Co., Ltd., Seoul (KR)

(72) Inventors: KwangHyun BAEK, Paju-si (KR); Intae KO, Paju-si (KR)

(21) Appl. No.: 18/982,937

(22) Filed: Dec. 16, 2024

(30) Foreign Application Priority Data
Dec. 29, 2023 (KR) 10-2023-0196752

(51) Int. Cl. H10H 29/855; G06F 3/044; H10H 29/34; H10H 29/80; H10H 29/852; H10K 59/35; H10K 59/40; H10K 59/80; H10K 59/88

(52) U.S. Cl. CPC H10H 29/8552; G06F 3/0445; H10H 29/34; H10H 29/852; H10H 29/942; H10K 59/353; H10K 59/40; H10K 59/873; H10K 59/8792; H10K 59/88; G06F 2203/04111

(57) ABSTRACT

Disclosed is a display apparatus capable of selectively controlling a viewing angle and improving optical characteristics. An apparatus includes a pixel array including a pixel circuit and a plurality of subpixels including first and second light emitting elements connected to the pixel circuit. The apparatus includes an encapsulation layer on the pixel array to seal a light emitting element layer. The apparatus includes a touch sensor array including a black matrix, a sensor electrode and a dummy electrode on the encapsulation layer and overlapping the non-emission area of the pixel array. The apparatus includes a light control array on the touch sensor array. The sensor electrode may be disposed in a non-emission area of a first type subpixel among the plurality of subpixels, and the dummy electrode may be disposed in a non-emission area of a second type subpixel and a third type subpixel among the plurality of subpixels.

### CROSS-REFERENCE TO RELATED APPLICATION

This application claims the benefit of the Korean Patent Application No. 10-2023-0196752 filed on Dec. 29, 2023, which is hereby incorporated by reference as if fully set forth herein.

### BACKGROUND

### Technical Field

The present disclosure relates to a display apparatus capable of controlling a viewing angle.

### Description of the Related Art

The display apparatus may be used in various electronic devices. The display apparatus may include a touch sensor embedded therein.

Among the display apparatus mounted on a vehicle, the display apparatus disposed in front of the passenger seat needs to limit the viewing angle to the driver according to the driver's driving situation. The display apparatus needs to limit the viewing angle according to a user's request for privacy protection and information protection.

### BRIEF SUMMARY

In the prior art, display apparatuses used security films superimposed on the display panel to limit the viewing angle of displayed images. However, the security film could significantly reduce the luminance of the display and impose a fixed viewing angle, causing inconvenience for the user. Accordingly, various embodiments of the present disclosure is directed to providing a display apparatus that substantially obviate one or more problems due to limitations and disadvantages of the related art.

An aspect of the present disclosure provides a display apparatus capable of selectively controlling a viewing angle and improving optical characteristics.

Additional advantages and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

Various embodiments of a display apparatus includes a pixel array including a pixel circuit and a plurality of subpixels including a first light emitting element and a second light emitting element connected to the pixel circuit; an encapsulation layer disposed on the pixel array to seal a light emitting element layer including the first light emitting element and the second light emitting element; a touch sensor array including a black matrix, a sensor electrode and a dummy electrode disposed on the encapsulation layer and overlapping a non-emission area of the pixel array; and a light control array including a first light control element overlapping the first light emitting element and a second light control element overlapping the second light emitting element disposed on the touch sensor array, wherein the sensor electrode may be disposed in a non-emission area of a first type subpixel among the plurality of subpixels, and the dummy electrode may be disposed in a non-emission area of a second type subpixel and a third type subpixel among the plurality of subpixels.

It is to be understood that both the foregoing general description and the following detailed description of the present disclosure are exemplary and explanatory and are intended to provide further explanation of the disclosure as claimed.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a diagram schematically illustrating a configuration of a display apparatus according to an embodiment of the present disclosure.

FIG. 2 is a cross-sectional view schematically illustrating an example of a structure of a display panel according to an embodiment of the present disclosure.

FIG. 3 is a diagram schematically illustrating a configuration of a subpixel according to an embodiment of the present disclosure.

FIGS. 4A and 4B are diagrams illustrating examples of structures of the first and second light control elements according to an embodiment of the present disclosure.

FIG. 5 is a diagram illustrating a display apparatus for a vehicle to which the display apparatus according to an embodiment of the present disclosure is applied.

FIG. 6 is an equivalent circuit diagram illustrating an example of a configuration of a subpixel according to an embodiment of the present disclosure.

FIG. 7 is a diagram illustrating an example of a driving waveform of a subpixel according to an embodiment of the present disclosure.

FIG. 8 is an enlarged plan view illustrating an example of an area A structure in the display panel according to an embodiment of the present disclosure illustrated in FIG. 1.

FIG. 9 is a plan view illustrating an example of an area A structure shown in FIG. 8 including a black matrix.

FIG. 10 is an enlarged plan view illustrating an example of a structure of a pixel area among areas A shown in FIG. 8.

FIG. 11 is a plan view illustrating an example of a structure of a pixel area illustrated in FIG. 10 including a black matrix.

FIG. 12 is a cross-sectional view illustrating an example of a structure of a subpixel area taken along a line I-I′ in a pixel area illustrated in FIG. 11.

FIG. 13 is a cross-sectional view illustrating an example of another structure of a subpixel area according to an embodiment of the present disclosure.

FIG. 14 is an enlarged plan view illustrating an example of a structure of a contact part in a pixel area illustrated in FIG. 11.

FIG. 15 is a cross-sectional view illustrating an example of a structure of a contact part taken along a line II-II′ shown in FIG. 14.

FIGS. 16A and 16B are diagrams comparing light progression paths in a subpixel area of a display panel according to a comparative example and an embodiment of the present disclosure.

FIG. 17 is a graph illustrating a light leakage reduction effect of a display apparatus according to an embodiment of the present disclosure as compared to a comparative example.

FIGS. 18 and 19 are cross-sectional views schematically illustrating a structure of a subpixel of a display panel according to an embodiment of the present disclosure.

FIG. 20 is graphs illustrating a viewing angle cut-off ratio enhancement effect of a display apparatus according to an embodiment of the present disclosure.

FIGS. 21A and 21B are graphs illustrating a color difference reduction effect of a display apparatus according to an embodiment of the present disclosure compared to a comparative example.

### DETAILED DESCRIPTION

Advantages and features of the present disclosure, and implementation methods thereof will be clarified through following aspects described with reference to the accompanying drawings. The present disclosure may, however, be embodied in different forms and should not be construed as limited to the aspects set forth herein. Rather, these aspects are provided so that this disclosure will be thorough and complete, and will fully convey the scope of the present disclosure to those skilled in the art. Further, the present disclosure is only defined by scopes of claims.

A shape, a size, a dimension (e.g., length, width, height, thickness, radius, diameter, area, etc.), a ratio, an angle, and a number disclosed in the drawings for describing aspects of the present disclosure are merely an example, and thus, the present disclosure is not limited to the illustrated details.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout the specification. In the following description, when the detailed description of the relevant known function or configuration is determined to unnecessarily obscure the important point of the present disclosure, the detailed description will be omitted. In a case where ‘comprise,’ ‘have,’ and ‘include’ described in the present specification are used, another part may be added unless ‘only’ is used. The terms of a singular form may include plural forms unless referred to the contrary.

In construing an element, the element is construed as including an error range although there is no explicit description.

In describing a position relationship, for example, when a position relation between two parts is described as “on,” “over,” “under,” and “next,” one or more other parts may be disposed between the two parts unless a more limiting term, such as “just” or “direct(ly)” is used.

In describing a time relationship, for example, when the temporal order is described as, “after,” “subsequent,” “next,” and “before,” a case which is not continuous may be included unless a more limiting term, such as “just,” “immediate(ly),” or “direct(ly)” is used.

It will be understood that, although the terms “first,” “second,” etc., may be used herein to describe various elements, these elements should not be limited by these terms. These terms are only used to distinguish one element from another. For example, a first element could be termed a second element, and, similarly, a second element could be termed a first element, without departing from the scope of the present disclosure.

In describing the elements of the present disclosure, the terms “first,” “second,” “A,” “B,” “(a),” “(b),” etc., may be used. These terms are intended to identify the corresponding elements from the other elements, and basis, order, sequence, or number of the corresponding elements should not be defined or limited by these terms. As for the expression that an element or a layer is “connected,” “coupled,” or “adhered” to another element or layer, the element or layer may not only be directly connected or adhered to another element or layer, but also be indirectly connected or adhered to another element or layer with one or more intervening elements or layers “disposed” between the elements or layers, unless otherwise specified.

The term “at least one” should be understood as including any and all combinations of one or more among the associated listed elements. For example, the meaning of “at least one or more of a first element, a second element, and a third element” denotes the combination of all elements proposed from two or more of the first element, the second element, and the third element as well as the first element, the second element, or the third element.

Features of various aspects of the present disclosure may be partially or overall coupled to or combined with each other, and may be variously inter-operated with each other and driven technically as those skilled in the art may sufficiently understand. The aspects of the present disclosure may be carried out independently from each other, or may be carried out together in co-dependent relationship.

Hereinafter, the aspect of the present disclosure will be described with reference to the accompanying drawings. Since a scale of each of elements shown in the accompanying drawings is different from an actual scale for convenience of description, the present disclosure is not limited to the shown scale. Further, all the components of each display apparatus according to all aspects of the present disclosure are operatively coupled and configured.

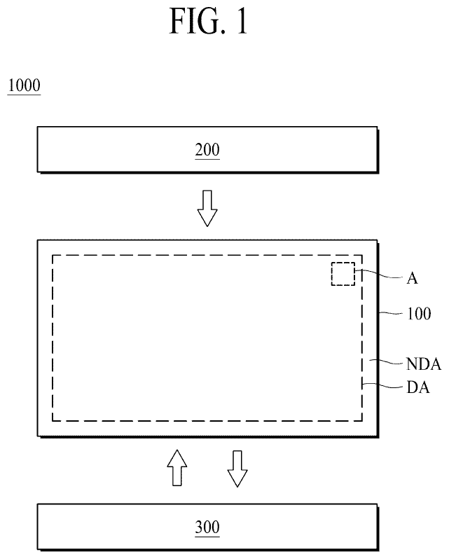

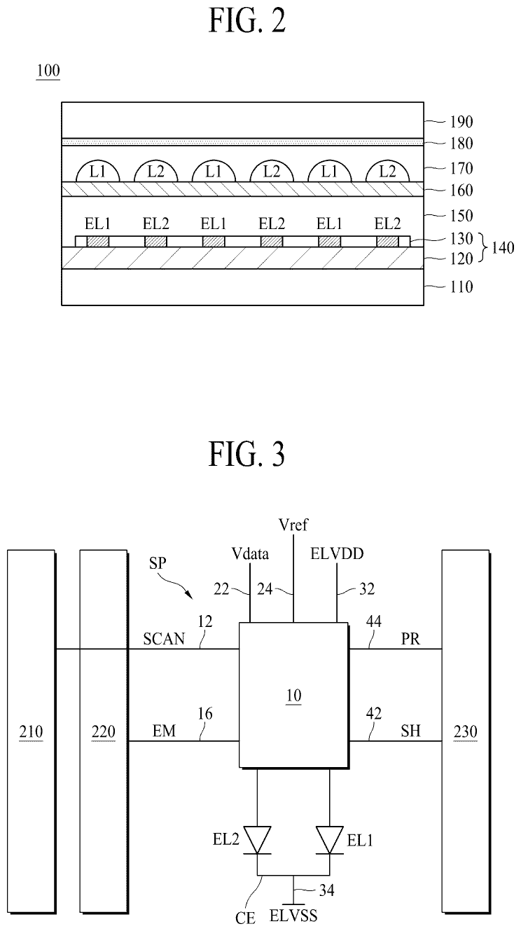

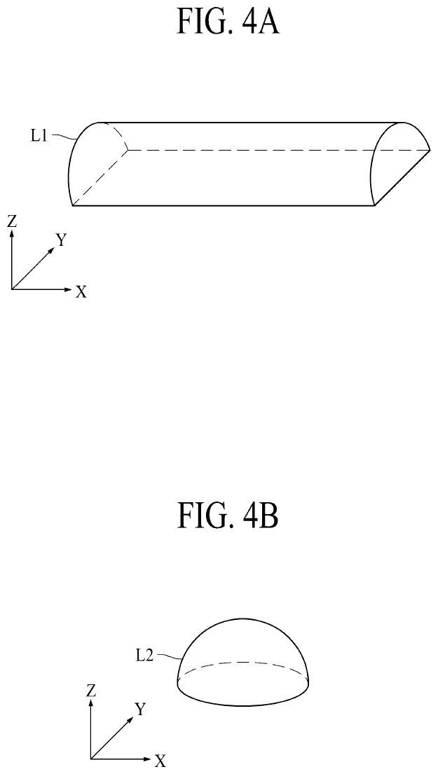

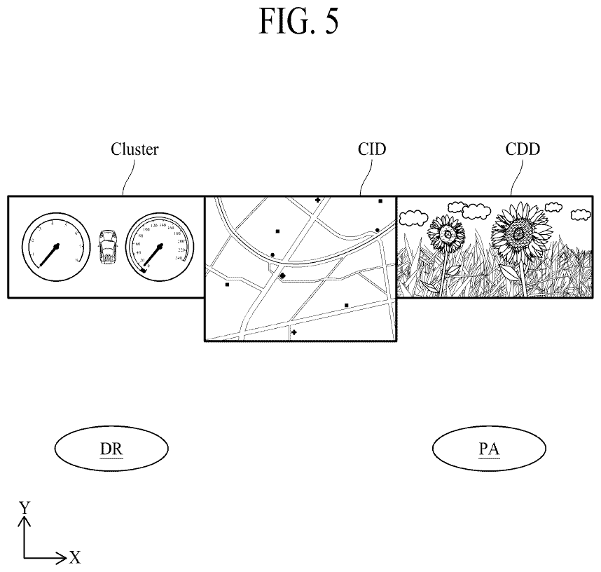

FIG. 1 is a diagram schematically illustrating a configuration of a display apparatus according to an embodiment of the present disclosure, FIG. 2 is a cross-sectional view schematically illustrating an example of a structure of a display panel according to an embodiment of the present disclosure, FIG. 3 is a diagram schematically illustrating a configuration of a subpixel according to an embodiment, FIGS. 4A and 4B are diagrams illustrating examples of structures of the first and second light control elements according to an embodiment of the present disclosure, and FIG. 5 is a diagram illustrating a display apparatus for a vehicle to which the display apparatus according to an embodiment of the present disclosure is applied.

The display apparatus 1000 according to an embodiment may provide both a display function for displaying an image and a touch sensing function for sensing the presence or absence of a user's touch and/or touch coordinates.

The display apparatus 1000 according to an embodiment may be an electroluminescent display apparatus including a touch sensor or a micro light emitting diode display apparatus. An electroluminescent display apparatus including a touch sensor may be an organic light emitting diode (OLED) display apparatus, a quantum-dot light emitting diode display apparatus, or an inorganic light emitting diode display apparatus.

Referring to FIG. 1, the display apparatus 1000 may include a display panel 100, a display driving circuit 200 for driving the display panel 100, and a touch sensing circuit 300 for driving and sensing a touch sensor array embedded into the display panel 100. The display apparatus 1000 may further include a power management circuit for generating and supplying a plurality of power voltages required for operations of the display panel 100, the display driving circuit 200, and the touch sensing circuit 300.

The display panel 100 may be a rigid display panel, or a flexible display panel capable of shape deformation such as a foldable, bendable, rollable, and stretchable display panel.

The display panel 100 may include a display area DA displaying an image and a non-display area NDA that is a bezel area surrounding the display area DA and positioned at the outer portion. The display panel 100 may further include a touch sensor array disposed in the display area DA to sense a user's touch.

The display panel 100 may display an image using the display area DA in which a plurality of subpixels is arranged in a matrix form. The pixel matrix of the display area DA may include a plurality of row lines consisting of a plurality of subpixels arranged in a first direction X and a plurality of column lines consisting of a plurality of subpixels arranged in a second direction Y. The display panel 100 may include a plurality of signal lines including a plurality of gate lines, a plurality of data lines, a plurality of power lines, and the like connected to a plurality of subpixels.

The plurality of subpixels may include a red subpixel emitting red light, a green subpixel emitting green light, and a blue subpixel emitting blue light. The plurality of subpixels may further include a white subpixel emitting white light. The unit pixel may include at least two subpixels.

The display driving circuit 200 may include a data driver that supplies a data signal to a plurality of data lines of the display panel 100, a gate driver that supplies a gate signal to a plurality of gate lines, and a timing controller controls the operation of the data driver and the gate driver.

The touch sensing circuit 300 may include a touch driving circuit that supplies a touch driving signal to a touch sensor array embedded into the display panel 100, and receives a readout signal from the touch sensor array to generate sensing data, and a touch controller that detects the presence or absence of a touch and a touch coordinate position based on sensing data supplied from the touch driving circuit, and the like.

The touch sensor array may use a self-capacitance method that senses a change in self-capacitance according to a touch, or a mutual-capacitance method that senses a change in mutual-capacitance according to a touch.

The display panel 100 according to an embodiment may control a viewing angle according to a viewing angle mode. The display area DA of the display panel 100 may display an image in a first viewing angle mode in which a viewing angle with respect to the first direction is relatively wide or a second viewing angle mode in which a viewing angle with respect to the first direction is narrower than that of the first viewing angle mode. The first viewing angle mode may be expressed as a wide viewing angle mode or a shared mode. The second viewing angle mode may be expressed as a narrow viewing angle mode or a privacy mode. The display area DA of the display panel 100 may be driven in a switchable privacy mode (SPM) capable of switching the sharing mode and the privacy mode.

Referring to FIG. 2, the display panel 100 according to an embodiment may include a pixel array 140 including a circuit element layer 120 including a plurality of transistors and a plurality of signal lines disposed on the substrate 110, and a light emitting element layer 130 including a plurality of light emitting elements EL1 and EL2 disposed on the circuit element layer 120, and an encapsulation layer 150 disposed on the pixel array 140 to seal the light emitting clement layer 130. The display panel 100 may include a touch sensor array 160 including a plurality of sensor electrodes disposed on the encapsulation layer 150, and a light control array 170 including a plurality of light control elements L1 and L2 disposed on the touch sensor array 160. The display panel 100 may further include a cover substrate 190 coupled to the light control array 170 by an optical clear adhesive (OCA) 180.

The touch sensor array 160 according to an embodiment may include a sensor electrode, a dummy electrode, and a black matrix disposed to overlap non-emission areas of the light emitting elements EL1 and EL2. At least one of the sensor electrode, the dummy electrode, and the black matrix according to an embodiment overlaps end portions of the light control elements L1 and L2 to block light, thereby preventing light leakage due to leakage light or reflected light. At least one of the sensor electrode, the dummy electrode, and the black matrix according to an embodiment does not overlap the end portion of the light control element L1 for the wide viewing angle, thereby preventing the limitation of the wide viewing angle. Meanwhile a detailed description thereof will be given later.

Referring to FIGS. 2 and 3, the subpixel SP according to an embodiment capable of controlling a viewing angle includes a first light emitting element EL1, a second light emitting clement EL2, and a pixel circuit 10 for dividing and driving the first and second light emitting elements EL1 and EL2 according to a viewing angle mode, and a first light control element (L1 of FIG. 2) may be overlapped on the first light emitting element EL1, and a second light control clement (L2 of FIG. 2) may be overlapped on the second light emitting element EL2.

The subpixel SP according to an embodiment may drive the first light emitting element EL1 in the first viewing angle mode and emit light having the first viewing angle through the first light control element L1. The subpixel SP may drive the second light emitting element EL2 in the second viewing angle mode and emit light having a second viewing angle narrower than the first viewing angle through the second light control element L2.

Referring to FIG. 4A, the first light control element L1 may have a half-cylindrical lens structure long in the first direction X, and the lens structure is not limited thereto. Referring to FIG. 4B, the second light control element L2 may have a half-spherical lens structure, and the lens structure is not limited thereto. In an embodiment, the first light control element L1 and the second light control element L2 may control (or limit) differently a viewing angle in the first direction X and control (or limit) equally a viewing angle in the second direction Y.

Depending on the embodiment, the light control elements L1 and L2 may be formed of a fluid material, a semi-fluid material, or a solid. The material and configuration of the light control elements L1 and L2 are not limited to the above-described examples. In addition, in some cases, the light control elements L1 and L2 may be referred to as a light control layer, a light control configuration, a lens, or a viewing angle control unit, but are not limited to these terms.

In FIGS. 4A and 4B, the first direction X may represent the left and right directions (e.g., horizontal directions) of the display panel 100, the second direction Y may represent the up and down direction (e.g., vertical direction) of the display panel 100, and the third direction Z may represent the front and rear directions (e.g., thickness direction) of the display panel 100.

In the first viewing angle mode, each subpixel SP of the display panel 100 drives the first light emitting element EL1 and does not limit the path of light emitted from the first light emitting element EL1 to within a specific angle in the first direction X, thereby providing light having a wide viewing angle.

In the second viewing angle mode, each subpixel SP of the display panel 100 may drive the second light emitting element EL2 and limit a path of light emitted from the second light emitting element EL2 through the second light control element L2 to within a specific cut-off angle in the first direction X to provide light having a narrow viewing angle.

The first light control element L1 and the second light control element L2 may control the path of light in the second direction Y to be within the cut-off angle to be controlled at a narrow viewing angle. Accordingly, when the display apparatus 1000 is applied to a vehicle as shown in FIG. 5, an image displayed on the display apparatus 1000 may be prevented from being reflected by the front glass of the vehicle to interfere with the driver's view.

The subpixel SP according to an embodiment may receive the data voltage Vdata from the data driver of the display driving circuit 200 through any one data line 22. The subpixel SP may receive the scan signal SCAN from the gate driver of the display driving circuit 200 through at least one gate line 12, and may receive the emission control signal EM through at least one gate line 16. The subpixel SP may receive the first mode signal SH from the gate driver of the display driving circuit 200 through any one gate line 42, and may receive the second mode signal PR through any one gate line 44. The subpixel SP according to an embodiment may receive the high-potential power voltage ELVDD from the power management circuit through the first power line 32, the low-potential power voltage ELVSS through the common electrode (cathode electrode) CE and the second power line 34, and may receive the reference voltage Vref through the reference line 24.

The gate driver may be embedded and disposed in the non-display area NDA of the display panel 100, and it is not limited there to, the gate driver may be distributed and disposed in the display area DA. The gate driver according to an embodiment may be embedded in the display panel 100 in a gate in panel (GIP) type consisting of transistors formed in the same process as transistors of the display area DA.

The gate driver may include at least one scan driver 210 driving at least one gate line 12 and at least one emission control driver 220 driving at least one gate line 16. The number of gate lines connected to the subpixel SP, the number of scan drivers 210, and the number of emission control drivers 220 may be variously changed according to a detailed configuration of a pixel circuit constituting the subpixel SP.

The scan driver 210 may generate and supply at least one scan signal SCAN to at least one gate line 12 disposed in each of the plurality of pixel row lines.

The emission control driver 220 may generate and supply at least one emission control signal EM to at least one gate line 16 disposed in each of the plurality of pixel row lines.

In an embodiment, the gate driver may further include a mode control unit 230 for supplying mode signals SH and PR to the gate lines 42 and 44.

The mode control unit 230 may generate and supply a first mode signal SH through any one gate line 42 to each of a plurality of pixel row lines using a mode selection signal, and may generate and supply a second mode signal PR through any one of the gate lines 44. The mode control unit 230 may selectively drive the first light emitting element EL1 and the second light emitting element EL2 of each subpixel SP by using the first mode signal SH and the second mode signal PR.

In an embodiment, the first and second mode signals SH and PR may be supplied from the light emission control driver 220.

At least one of an LTPS transistor using a low temperature polysilicon (LTPS) semiconductor and an oxide transistor using a metal-oxide semiconductor may be applied to a plurality of transistors disposed in the display area DA of the display panel 100 and the non-display area NDA including the gate driver. The display panel 100 according to an embodiment may be configured such that an LTPS transistor and an oxide transistor coexist to reduce power consumption.

Referring to FIG. 5, a plurality of display apparatus disposed on a vehicle dashboard may include a cluster, a center information display CID, and a co-driver display CDD. A display apparatus that limits the viewing angle to within the cut-off angle in only the second direction Y for safe driving may be applied to the cluster and the central information display CID mainly used by the driver DR. A display apparatus including a touch sensor may be applied to the central information display CID. The display apparatus 1000 capable of controlling the viewing angle in the first viewing angle mode and the second viewing angle mode as in the above-described embodiment may be applied to the co-driver display CDD used by the driver DR and the passenger PA.

The co-driver display CDD may be driven in a first viewing angle mode under the control of the host system when the driver DR is not driving, and may provide an image having a wide viewing angle in the first direction X to the driver DR and the passenger PA.

When the driver DR drives, the co-driver display CDD may be driven in the second viewing angle mode under the control of the host system, may limit the viewing angle to within the cut-off angle in the first direction X to provide an image having a narrow viewing angle to only the passenger PA, and may not provide an image to the driver DR so as not to interfere with driving.

The display apparatus 1000 according to an embodiment may be applied not only to a co-driver display CDD, but also to various display apparatus such as a mobile display, an IT display, and a TV display that selectively requires viewing angle control for privacy and information protection.

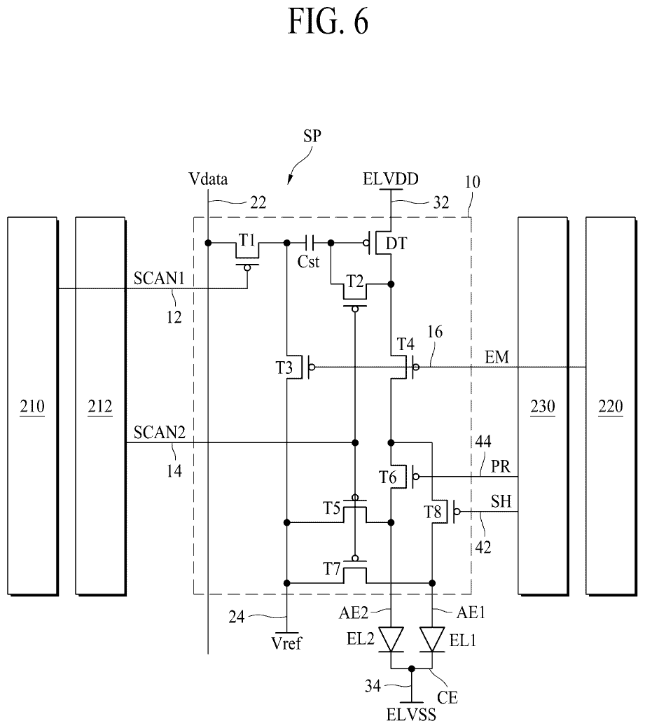

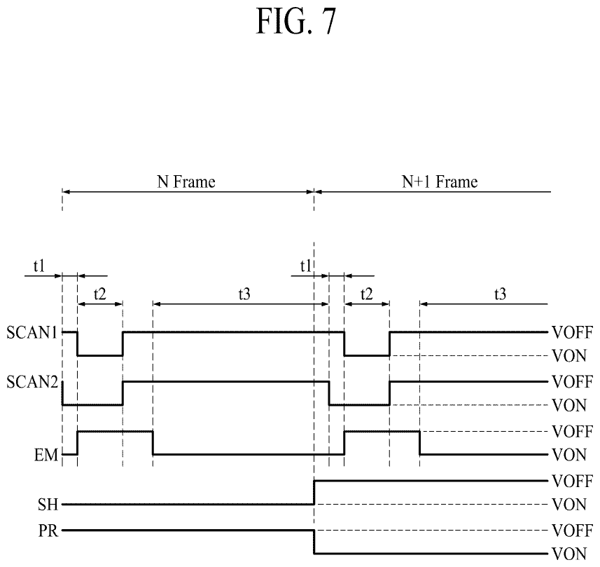

FIG. 6 is an equivalent circuit diagram illustrating an example of a configuration of a subpixel according to an embodiment of the present disclosure, and FIG. 7 is a diagram illustrating an example of a driving waveform of a subpixel according to an embodiment of the present disclosure.

Referring to FIG. 6, the subpixel SP may include first and second light emitting elements EL1 and EL2, and a pixel circuit 10 for separately driving the first and second light emitting elements EL1 and EL2. In an embodiment, the pixel circuit 10 may include a driving transistor DT, a plurality of switching transistors TI to T8, and a storage capacitor Cst, but is not limited thereto.

The pixel circuit 10 may receive the first scan signal SCAN1 from the first scan driver 210 through the first gate line 12, and may receive the second scan signal SCAN2 from the second scan driver 212 through the second gate line 14.

The pixel circuit 10 may receive the emission control signal EM from the first emission control driver 220 through the third gate line 16.

In an embodiment, the pixel circuit 10 may receive the first mode signal SH from the mode control unit 230 through the fourth gate line 42, and may receive the second mode signal PR through the fifth gate line 44.

In an embodiment, the pixel circuit 10 may receive the first mode signal SH from the second light emission control driver 220 through the fourth gate line 42, and may receive the second mode signal PR through the fifth gate line 44.

The pixel circuit 10 may receive the data signal Vdata from the data driver through the data line 22. The pixel circuit 10 may receive the high potential power voltage ELVDD from the power management circuit through the first power line 32, the low potential power voltage ELVSS through the second power line 34 and the common electrode CE, and the reference voltage Vref through the reference line 24.

In an embodiment, the second light emitting element EL2 may include a plurality of light emitting elements. For example, the second light emitting element EL2 may include a 2-1 light emitting element and a 2-2 light emitting element. In this case, the 2-1 light emitting element and the 2-2 light emitting element may be connected in parallel. According to an embodiment, the anode of the 2-1 light emitting element and the 2-2 light emitting element may be formed in common or be shared, but the present disclosure is not limited thereto. According to an embodiment, the second light emitting element EL2 may include three or more light emitting elements.

Referring to FIG. 7, the subpixel SP may be driven to include an initialization period t1, a sampling and writing period t2, and an emission period t3 for each frame period N and N+1. For convenience of description, in FIG. 7, the N frame period represents any one frame period of the first viewing angle mode, and the N+1 frame period represents any one frame period of the second viewing angle mode.

Each of the driving transistor DT and the plurality of switching transistors T1 to T8 of the pixel circuit 10 includes a gate electrode, a source electrode, and a drain electrode. Since the source electrode and the drain electrode are not fixed and may be changed according to the voltage and current direction applied to the gate electrode, one of the source electrode and the drain electrode may be expressed as the first electrode, and another one of the source electrode and the drain electrode may be expressed as the second electrode. The driving transistor DT and the plurality of switching transistors T1 to T8 of the pixel circuit 10 may use at least one of a polysilicon semiconductor, an amorphous silicon semiconductor, and an oxide semiconductor, and may use the P type or the N type and may be used in combination of the P type and the N type.

The first and second light emitting elements EL1 and EL2 may include the anode electrodes AE1 and AE2 individually connected to the eighth and sixth switching transistors T8 and T6, the cathode electrode CE receiving the low potential power voltage ELVSS from the second power line 34, and the light emitting layer disposed between the anode electrodes AE1 and AE2, and the cathode electrode CE. In the first and second light emitting elements EL1 and EL2, when driving current is supplied from the driving transistor DT through each of the eighth and sixth switching transistors T8 and T6, electrons from the cathode electrode CE are injected into the light emitting layer, and holes from the anode electrodes AE1 and AE2 are injected into the light emitting layer to emit light having a brightness proportional to the current value of the driving current by emitting fluorescent materials or phosphorescent materials by recombination of electrons and holes in the light emitting layer.

The gate electrode of the driving transistor DT may be connected to the storage capacitor Cst, the first electrode may be connected to the first power line 32 supplying the high potential power voltage ELVDD, and the second electrode may be connected to the first electrode of the fourth switching transistor T4. The driving transistor DT may be connected in common to the first electrodes of the sixth and eighth switching transistors T6 and T8 through the fourth switching transistor T4. The driving transistor DT may drive the first light emitting element EL1 through the fourth and eighth switching transistors T4 and T8, or may drive the second light emitting element EL2 through the fourth and sixth switching transistors T4 and T6. The driving transistor DT may control the light emission intensity of the first light emitting element EL1 through the fourth and eighth switching transistors T4 and T8 or may control the light emission intensity of the second light emitting element EL2 through the fourth and sixth switching transistors T4 and T6 by controlling the driving current according to the driving voltage charged in the storage capacitor Cst.

The storage capacitor Cst may be connected between the second electrode of the first switching transistor T1 and the gate electrode of the driving transistor DT to charge a driving voltage corresponding to the data voltage Vdata. The storage capacitor Cst may hold the charged driving voltage during the light emission period t3 during which the first switching transistor T1 is turned off, and supply the driving voltage to the driving transistor DT.

The first switching transistor T1 may be turned on or turned off in response to the first scan signal SCAN1 of the first gate line 12 disposed in the ith (i is a natural number) pixel row line. The first switching transistor T1 may supply the data voltage Vdata supplied through the data line 22 to the first electrode of the storage capacitor Cst during the sampling and writing period t2 in which the first scan signal SCAN1 has the gate-on voltage VON. The switching transistor T1 may be turned off during the initialization period t1 and the light emission period t3 in which the first scan signal SCAN1 has the gate-off voltage VOFF.

The second, fifth, and seventh switching transistors T2, T5, and T7 may be turned on or off in response to the second scan signal SCAN2 supplied to the second gate line 14 of the i-th pixel row line. The second, fifth, and seventh switching transistors T2, T5, and T7 may be turned on during the initialization period t1 and the sampling and writing period t2 in which the second scan signal SCAN2 has the gate-on voltage VON, and may be turned off during the light emission period t3 in which the second scan signal SCAN2 has the gate-off voltage VOFF.

The second switching transistor T2 may connect the driving transistor DT in a diode structure by connecting the gate electrode of the driving transistor DT to the second electrode during the initialization period t1 and the sampling and writing period t2 in response to the second scan signal SCAN2. The second switching transistor T2 may charge the storage capacitor Cst by compensating the threshold voltage Vth of the driving transistor DT. Accordingly, the storage capacitor Cst may charge the data voltage compensated for the threshold voltage Vth of the driving transistor DT.

The fifth switching transistor T5 may supply the reference voltage Vref supplied through the reference line 24 to the anode electrode AE2 of the second light emitting element EL2 during the initialization period t1 and the sampling and writing period t2 in response to the second scan signal SCAN2.

The seventh switching transistor T7 may supply the reference voltage Vref supplied through the reference line 24 to the anode electrode AE1 of the first light emitting element EL1 during the initialization period t1 and the sampling and writing period t2 in response to the second scan signal SCAN2.

The third and fourth switching transistors T3 and T4 may be turned on or turned off in response to the light emission control signal EM supplied to the third gate line 16 of the i-th pixel row line. The third and fourth switching transistors T3 and T4 may be turned on during the initialization period t1 and the light emission period t3 in which the light emission control signal EM has the gate-on voltage VON. The third and fourth switching transistors T3 and T4 may be turned off during the sampling and writing period t2 and a period between the sampling and writing period t2 and the light emission period t3 in which the light emission control signal EM has the gate-off voltage VOFF.

The third switching transistor T3 may supply the reference voltage Vref supplied through the reference line 24 to the first electrode of the storage capacitor Cst during the initialization period t1 and the light emission period t3 in response to the light emission control signal EM.

The fourth switching transistor T4 may connect the driving transistor DT to the sixth and eighth switching transistors T6 and T8 during the initialization period t1 and the light emission period t3 in response to the light emission control signal EM.

The eighth switching transistor T8 may be turned on or off in response to the first mode signal SH supplied to the fourth gate line 42 of the i-th pixel row line. The eighth switching transistor T8 may be turned on during the driving period N frame of the first viewing angle mode in which the first mode signal SH has the gate-on voltage VON, and may be turned off during the driving period N+1 frame of the second viewing angle mode in which the first mode signal SH has the gate-off voltage VOFF.

The eighth switching transistor T8 may connect the fourth switching transistor T4 to the first light emitting element EL1 during the driving period N frame of the first viewing angle mode in response to the first mode signal SH.

During the light emission period t3 of the driving period N frame of the first viewing angle mode, the driving transistor DT may drive the first light emitting element EL1 through the fourth and eighth switching transistors T4 and T8. Accordingly, the subpixel SP may provide light of the first viewing angle through the first light emitting element EL1 and the first light control element (see L1 of FIG. 4A).

The sixth switching transistor T6 may be turned on or off in response to the second mode signal PR supplied to the fifth gate line 44 disposed in the i-th pixel row line. The sixth switching transistor T6 may be turned on during the driving period N+1 frame of the second viewing angle mode in which the second mode signal PR has the gate-on voltage VON, and may be turned off during the driving period N frame of the first viewing angle mode in which the second mode signal PR has the gate-off voltage VOFF.

The sixth switching transistor T6 may connect the fourth switching transistor T4 to the second light emitting element EL2 during the driving period N+1 frame of the second viewing angle mode in response to the second mode signal PR.

During the light emission period t3 of the driving period N+1 frame of the second viewing angle mode, the driving transistor DT may drive the second light emitting element EL2 through the fourth and sixth switching transistors T4 and T6. Accordingly, the subpixel SP may provide light of the second viewing angle through the second light emitting element EL2 and the second light control element L2 (FIG. 4B).

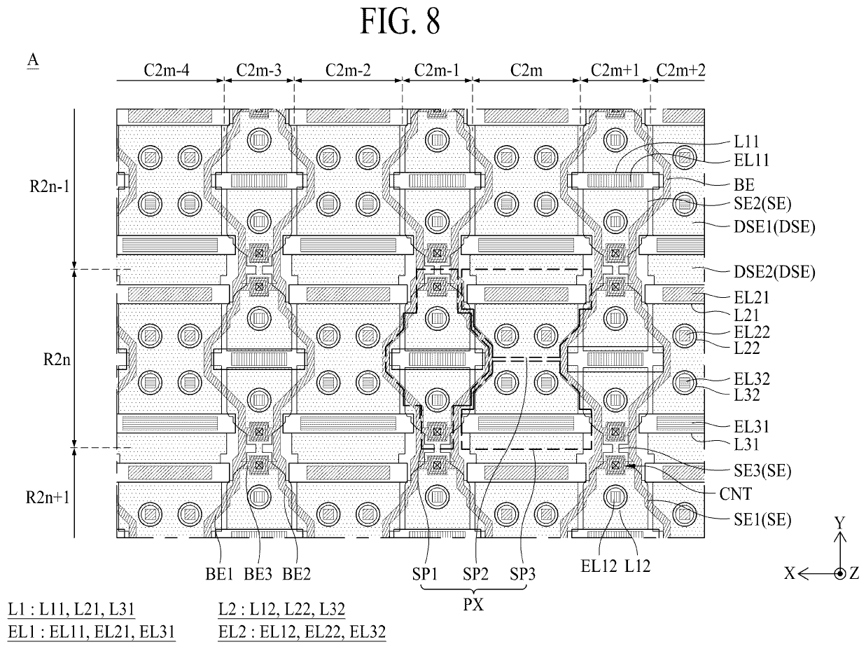

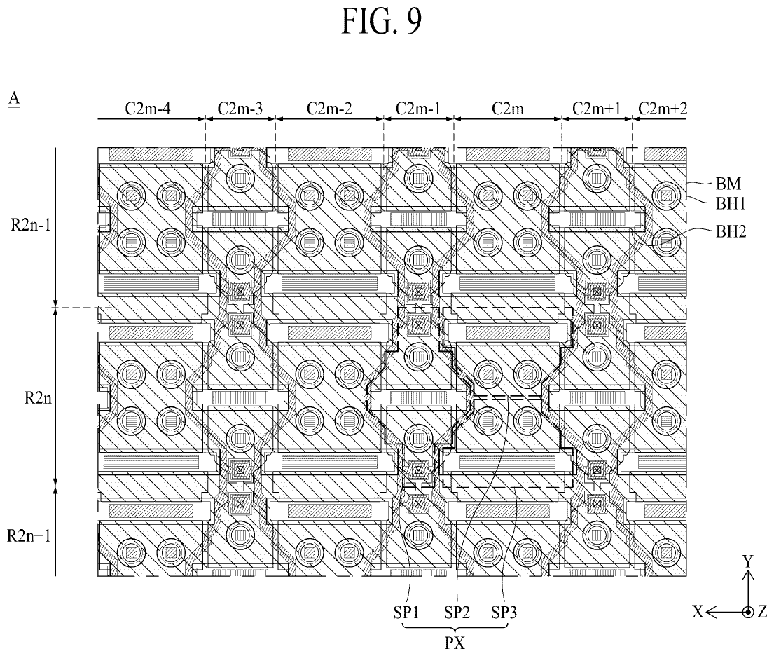

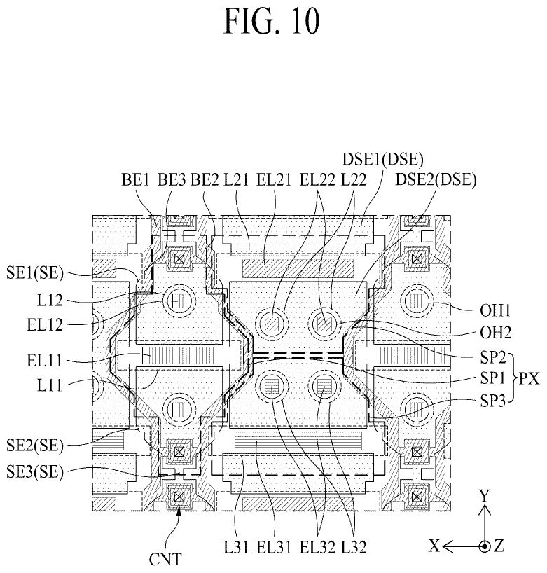

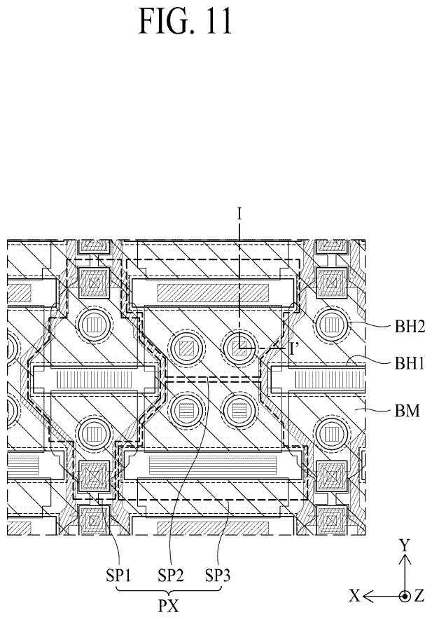

FIG. 8 is an enlarged plan view illustrating an example of an area A structure in the display panel according to an embodiment illustrated in FIG. 1, FIG. 9 is a plan view illustrating an example of an area A structure shown in FIG. 8 including a black matrix, FIG. 10 is an enlarged plan view illustrating an example of a structure of a pixel area among areas A shown in FIG. 8, and FIG. 11 is a plan view illustrating an example of a structure of a pixel area illustrated in FIG. 10 including a black matrix.

Referring to FIGS. 8 to 11, area A is an enlarged view of a plurality of pixel areas on the display panel 100 according to an embodiment illustrated in FIG. 1. The area A of the display panel 100 according to an embodiment may have a structure in which a pixel array, a touch sensor array, and a light control array at least partially overlap. The pixel array may include a plurality of subpixels SP1, SP2, and SP3 having a plurality of light emitting elements EL1:EL11, EL21, EL31, and EL2:EL12, EL22, EL32. The touch sensor array may include a plurality of sensor electrodes SE, a bridge electrode BE, a dummy electrode DSE, and a black matrix BM. The light control array may include a plurality of light control elements L1: L11, L21, L31, and L2: L12, L22, L32.

The pixel array may include a 2n−1 row line R2n−1, (n is a natural number) and a 2n row line R2n including a plurality of subpixels SP1, SP2, and SP3 arranged in the first direction X, and a 2m−1 column line C2m−1, (m is a natural number) and a 2m column line C2m including a plurality of subpixels SP1, SP2, and SP3 arranged in the second direction Y.

The 2m−1 column line C2m−1 may include a plurality of first type subpixels SP1 arranged in the second direction Y. The 2m column line C2m may include a plurality of second and third type subpixels SP2 and SP3 alternately arranged in the second direction Y.

Each of the 2n−1 row line R2n−1 and the 2n row line R2n may include a plurality of first to third type subpixels SP1, SP2, and SP3 in which the first type subpixels SP1 and the second to third type subpixels SP2 and SP3 are alternately disposed in the first direction X.

Each pixel PX may include a first type subpixel SP1 emitting first color light, a second type subpixel SP2 emitting second color light, and a third type subpixel SP3 emitting third color light. The first type subpixel SP1 may be disposed adjacent to the second and third type subpixels SP2 and SP3 in the first direction X. The second and third type subpixels SP2 and SP3 may be disposed adjacent and parallel to each other in the second direction Y.

The first type subpixel SP1 may include a first light emitting element EL11 (or 1-1 light emitting clement), a first light control element L11 (or 1-1 light control element) overlapping on the first light emitting element EL11, at least one second light emitting element EL12 (or 1-2 light emitting element), and at least one second light control element L12 (or 1-2 light control element) overlapping on the at least one second light emitting element EL12. Other names of the light emitting element and light control clement apply the same manner. The light emission area of the first light emitting element EL11 may have a structure longer in the first direction X than the second direction Y.

In an embodiment, in the first type subpixel SP1, two second light emitting elements EL12 may be disposed to be separated from each other with the first light emitting element EL11 interposed therebetween in the second direction Y. The two second light emitting elements EL12 may have a parallel connection structure in which anode electrodes are connected to each other.

The second light emitting element EL12 and the second light control element L12 of the first type subpixel SP1 may be disposed adjacent to the second light emitting element EL12 and the second light control element L12 of another first type subpixel SP1 adjacent to each other in the second direction Y.

In another embodiment, a plurality of second light control elements L12 may be disposed on one second light emitting element EL12 in the first type subpixel SP1. One light emitting layer may be commonly disposed under a plurality of second light control elements L12 shown in FIG. 10. However, in this case, the light emitting layer of the second light emitting element EL12 may not be disposed under the region corresponding to the first light emitting element EL11, and a light emitting layer dedicated to the first light emitting element EL11 may be separately disposed.

The first type subpixel SP1 may be a red subpixel having first and second light emitting elements EL11 and EL12 that emit red light.

The second type subpixel SP2 may include a first light emitting element EL21 (or 2-1 light emitting element), a first light control element L21 (or 2-1 light control element) overlapped on the first light emitting element EL21, at least one second light emitting element EL22 (or 2-2 light emitting element), and at least one second light control element L22 (or 2-2 light control element) overlapped on the at least one second light emitting element EL22.

In the second type subpixel SP2, two second light emitting elements EL22 may be disposed in parallel in the first direction X, and the first light emitting element EL21 and the two second light emitting elements EL22 may be separated from each other in the second direction Y. The two second light emitting elements EL22 may have a parallel connection structure in which anode electrodes are connected to each other.

In the second type subpixel SP2, two second light control elements L22 may be disposed in parallel in the first direction X, and the first light control element L21 and the two second light control elements L22 may be disposed separately in the second direction Y.

The second type subpixel SP2 may be a green subpixel having first and second light emitting elements EL21 and EL22 that emit green light.

In the third type subpixel SP3, two second light emitting elements EL32 (or 3-2 light emitting elements) may be disposed in parallel in the first direction X, and the first light emitting clement EL31 (or 3-1 light emitting elements) and the two second light emitting elements EL32 may be separated from each other in the second direction Y. The two second light emitting elements EL32 may have a parallel connection structure in which anode electrodes are connected to each other.

In the third type subpixel SP3, two second light control elements L32 (or 3-2 light control elements) may be disposed in parallel in the first direction X, and the first light control clement L31 (or 3-1 light control elements) and the two second light control elements L32 may be disposed separately in the second direction Y.

The second light emitting element EL22 and the second light control element L22 of the second type subpixel SP2 may be disposed adjacent to the second light emitting element EL32 and the second light control element L32 of the third type subpixel SP3 of the same pixel PX adjacent to each other in the second direction Y. The first light emitting element EL31 and the first light control element L31 of the third type subpixel SP3 may be disposed adjacent to the first light emitting element EL21 and the first light control element L21 of the second type subpixel SP2 of another pixel PX adjacent to each other in the second direction Y.

The third type subpixel SP3 may be a blue subpixel having first and second light emitting elements EL31 and EL32 that emit blue light.

According to an embodiment, a color of light emitted by each of the first type subpixel SP1, the second type subpixel SP2, and the third type subpixel SP3 may be a different color from that described above. Also, in some cases, the arrangement of the light control elements L1: L11, L21, L31, and L2: L12, L22, L32 in the first type subpixel SP1 and the second type subpixel SP2, and the arrangement of the light emitting elements may be different.

The size of the first light emitting elements EL1: EL11, EL21, and EL31 may be larger than the size of the second light emitting elements EL2: EL12, EL22, and EL32. The second light emitting element EL2 may have a size smaller than that of the light emission area of the first light emitting element EL1 and a plurality of light emission areas separated in the second direction Y with the first light emitting element EL1 interposed therebetween. The size of the light incident surface of the first light control elements L1: L11, L21, and L31 may be set to be larger than the size (the size of the light emission area) of the first light emitting elements EL1: EL11, EL21, and EL31, so that the light emission efficiency may be improved. The size of the light incident surface of the second light control elements L2: L12, L22, and L32 may be set to be larger than the size (the size of the light emission area) of the second light emitting elements EL2: EL12, EL22, and EL32. A size of a light incident surface of the first light control element L1 may be larger than a size of a light incident surface of the second light control element L2. The light control element may have a light incident surface size proportional to the size of the light emission area of the corresponding light emitting element.

In an embodiment, the sizes of the first light emitting elements EL11, EL21, and EL31 may be different for each color to compensate for a deviation in light emission efficiency for each color of the first light emitting elements EL11, EL21, and EL31. In an embodiment, the sizes of the first light emitting element EL11 and the first light control element L11 of the first type subpixel SP1 may be the smallest, and the sizes of the first light emitting element EL21 and the first light control element L21 of the second type subpixel SP2 may be equal to or smaller than the sizes of the first light emitting element EL31 and the first light control element L31 of the third type subpixel SP3.

In an embodiment, the sizes of the second light emitting elements EL12, EL22, and EL32 may be different for each color, or the number of light emitting regions having the same size may be different for each color to compensate for a variation in light emission efficiency for each color of the second light emitting elements EL12, EL22, and EL32. In an embodiment, the sizes (number) of the second light emitting element EL12 and the second light control element L12 of the first type subpixel SP1 may be the smallest, and the sizes (number) of the second light emitting clement EL22 and the second light control element L22 of the second type subpixel SP2 may be equal to or smaller than the sizes (number) of the second light emitting element EL32 and the second light control element L32 of the third type subpixel SP3.

The touch sensor array may include a plurality of sensor electrodes SE, a plurality of dummy electrodes DSE, and a plurality of bridge electrodes BE disposed to overlap the non-emission area of the pixel array. The plurality of sensor electrodes SE and the plurality of dummy electrodes DSE may be disposed on the same layer to be separated from each other. The bridge electrode BE may be disposed on a different layer to overlap the sensor electrode SE and the dummy electrode DSE, and may electrically connect the plurality of sensor electrodes SE through the contact part CNT.

In an embodiment, a plurality of sensor electrodes SE may be disposed in a non-emission area of the first type subpixel SP1 along the 2m−1 column line C2m−1. A plurality of sensor electrodes SE may be separated in the second direction Y with the first light emitting element EL11 of the first type subpixel SP1 interposed therebetween.

Each of the plurality of sensor electrodes SE may include a first sensor electrode portion SE1 disposed in the non-emission area around the second light emitting element EL12 of the first type subpixel SP1 and a second sensor electrode portion SE2 disposed in the non-emission area around the second light emitting element EL22 of another second type subpixel SP2 adjacent to each other in the second direction Y. Each of the plurality of sensor electrodes SE may further include a third sensor electrode portion SE3 connecting the first sensor electrode portion SE1 to the second sensor electrode portion SE2 in the second direction Y.

In each of the first sensor electrode portion SE1 and the second sensor electrode portion SE2, a first portion surrounding the second light emitting element EL12 may have a relatively large area, a second portion overlapping any one of the contact parts CNT may have a smaller area than the first portion, and the third sensor electrode portion SE3 may have the smallest area. The first sensor electrode portion SE1 and the second sensor electrode portion SE2 may have structures symmetrical in the second direction Y with respect to the third sensor electrode portion SE3.

Each of the first sensor electrode portion SE1 and the second sensor electrode portion SE2 may be electrically connected to the bridge electrode BE through the contact part CNT adjacent to the third sensor electrode portion SE3 in the second direction Y. Two contact parts CNTs may be disposed in parallel in the second direction Y between the second light emitting elements EL12 of the first type subpixel SP1 adjacent to each other in the second direction Y, and the third sensor electrode portion SE3 may be disposed between the two contact parts CNT.

The first sensor electrode portion SE1 and the second sensor electrode portion SE2 may be connected to the third sensor electrode portion SE3, respectively, so that the first sensor electrode portion SE1, the second sensor electrode portion SE2, and the third sensor electrode portion SE3 may be disposed in an integrated pattern. The first sensor electrode portion SE1, the second sensor electrode portion SE2, and the third sensor electrode portion SE3 forming the integrated pattern may be disposed over the first type sub-pixel SP1 located at the 2n row line R2n and the first type sub-pixel SP1 located at the 2n+1 row line R2n+1, for example. More specifically, the first sensor electrode portion SE1 overlaps the non-emission area of the first type sub-pixel SP1 located in the 2n+1 row line R2n+1, the second sensor electrode portion SE2 overlaps the non-emission area of the first type sub-pixel SP1 located in the 2n row line R2n, and the third sensor electrode portion SE3 overlaps the non-emission area between the first type sub-pixel SP1 located in the 2n row line R2n and the first type sub-pixel SP1 located in the 2n+1 row line R2n+1, and may be integrated together with the first sensor electrode portion SE1 and the second sensor electrode portion SE2.

The first sensor electrode portion SE1 and the second sensor electrode portion SE2 may include an open part OH1 overlapping the light emission area of the second light emission clement EL12 and the second light control element L12, respectively. The size of the open part OH1 of each of the first and second sensor electrode portions SE1 and SE2 may be larger than the size of the light emission area of the second light emitting element EL12 and smaller than the size of the light incident surface of the second light control element L12. The ends of the first and second sensor electrode portions SE1 and SE2 overlapping the second light control element L12 together with the second light control element L12 may limit the radiation angle of light emitted from the second light emitting element EL12 to within the cut-off angles in the first and second directions X and Y and block light leakage.

The ends of the first sensor electrode portion SE1 and the second sensor electrode portion SE2 separated in the second direction Y with the first light emitting element EL11 of the first type subpixel SP1 interposed therebetween overlap an end portion of the first light control element L11 that does not overlap the first light emitting element EL11, so that the radiation angle of the light emitted from the first light emitting element EL11 together with the first light control element L11 may be limited to within the cut-off angle in the second direction Y and light leakage may be blocked.

In an embodiment, each of a plurality of bridge electrodes BEs may pass through non-emission areas of the first to third type subpixels SP1, SP2, and SP3 and may be disposed along the second direction Y.

The bridge electrode BE may include first and second bridge electrode portions BE1 and BE2 extending in the second direction Y or along the 2m−1 column line C2m−1 and a third bridge electrode portion BE3 connecting the first bridge electrode portion BE1 to the second bridge electrode portion BE2.

The first and second bridge electrode portions BE1 and BE2 may overlap the first sensor electrode SE around the second light emitting element EL12 of the first type subpixel SP1, and overlap the dummy electrode DSE around the second light emitting elements EL22 and EL32 of the second and third type subpixels SP2 and SP3, and may be symmetrical in the first direction X. The third bridge electrode portion BE3 may be electrically connected to the first sensor electrode portion SE1 and the second sensor electrode portion SE2 through the contact part CNT.

The first and second bridge electrode portions BE1 and BE2 extending along the 2m−1 column line C2m−1 from both sides of the 2m−1 column line C2m−1 may have a pattern shape in which a mutual interval in the first direction X varies along the second direction Y.

In an embodiment, the first and second bridge electrode portions BE1 and BE2 may have a maximum mutual interval in the first direction X in a non-emission area overlapping the dummy electrode DSE adjacent to the first light control element L11 of the first type subpixel SP1 in the first direction X.

In an embodiment, the first and second bridge electrode portions BE1 and BE2 may have a minimum mutual interval in the first direction X in a non-emission area partially overlapping the sensor electrode between a plurality of contact parts CNTs and the first light control elements L21 and L31 of the second and third type subpixels SP2 and SP3, that is, in an area connected to the third bridge electrode BE3.

In an embodiment, the first and second bridge electrode portions BE1 and BE2 may have a diagonal pattern shape or oblique pattern shape overlapping each other via the dummy electrode DSE and the sensor electrode SE between the maximum mutual interval portion and the minimum mutual interval portion.

A plurality of dummy electrodes DSE may be disposed in the non-emission area of the 2m column line C2m. The dummy electrode DSE may be disposed in a non-emission area of the second type subpixel SP2 and the third type subpixel SP3. The plurality of dummy electrodes DSE may include a first dummy electrode DSE1 disposed in the non-emission area around the second light emitting elements EL22 and EL32 of the second and third type subpixels SP2 and SP3 adjacent to each other in the second direction Y, and a second dummy electrode DSE2 disposed in the non-emission area between the first light emitting elements EL21 and EL31 of the second and third type subpixels SP2 and SP3 adjacent to each other in the second direction Y. The first dummy electrode DSEI may have an area larger than that of the second dummy electrode DSE2.

The first and second dummy electrodes DSE1 and DSE2 may be electrically floating electrodes that are not electrically connected to other electrodes. The floating first and second dummy electrodes DSE1 and DSE2 may reduce parasitic capacitance formed between the touch sensor array and the common cathode electrode of the pixel array, thereby reducing distortion of a touch driving signal and a touch sensing signal, thereby improving sensing performance.

The first dummy electrode DSEI may include an open part OH2 overlapping the light emission area of the second light emitting elements EL22 and EL32, and overlapping the second light control elements L22 and L32. The size of the open part OH2 of the first dummy electrode DSE1 may be larger than the size of the light emission areas of the second light emitting elements EL22 and EL32 and smaller than the size of the light incident surfaces of the second light control elements L22 and L32. Ends of the first dummy electrode DSE1 overlapping the second light control elements L22 and L32 together with the second light control elements L22 and L32 may limit the traveling directions of the light emitted from the second light emitting elements EL22 and EL32 to within a cut-off angle and block light leakage.

The first dummy electrode DSE1 may have a pattern shape including a portion having a maximum length in the first direction X in a non-emission area adjacent to the sensor electrode SE in the first direction X and a portion having a minimum length in the first direction X in a non-emission area between the first light control elements L11 of the first type subpixel SP1 adjacent in the first direction X.

The ends of the first dummy electrode DSE1 and the second dummy electrode DSE2 in the second direction Y overlap portions of the first light control elements L21 and L31 not overlapping the first light emitting elements EL21 and EL31, so that the direction of light emitted from the first light emitting elements EL21 and EL31 together with the first light control elements L21 and L31 may be limited to within a cut-off angle and light leakage may be prevented.

The second dummy electrode DSE2 may have a pattern shape including a portion in a non-emission area adjacent to the first light control element L31 of the third type subpixel SP3 in the second direction Y which has the maximum length in the first direction X, and a portion in a non-emission area adjacent to the first light control element L21 of the second type subpixel SP2 in the second direction Y which has the minimum length in the first direction X.

Referring to FIGS. 9 and 11, the touch sensor array may further include a black matrix BM disposed in a non-emission area of the pixel array.

The black matrix BM may include a first open part BH1 overlapping the first light emitting elements EL1: EL11, EL21, and EL31, and a second open part BH2 overlapping the second light emitting elements EL2: EL12, EL22, and EL32. The size of the first open part BH1 of the black matrix BM may be larger than the size of the light emission area of the second light emitting elements EL2: EL12, EL22, and EL32, and may be smaller or larger than the size of the light incident surface of the second light control element L2: L12, L22, and L32. The size of the second open part BH2 of the black matrix BM may be larger than the size of the light emission area of the first light emitting elements EL1: EL11, EL21, and EL31, and may be smaller or larger than the size of the light incident surface of the first light emitting elements L1: L11, L21, and L31.

In an embodiment, the sizes of the first open parts BH1 of the black matrix BM may be different for each subpixel in proportion to the sizes of the light emission areas of the first light emitting elements EL11, EL21, and EL31 and the sizes of the first light control elements L11, L21, and L31. In an embodiment, the sizes of the second open parts BH2 of the black matrix BM may be different for each subpixel in proportion to the sizes of the light emission areas of the second light emitting elements EL12, EL22, and EL32, and the sizes of the second light control elements L12, L22, and L32.

The end of the black matrix BM adjacent to or overlapped with the first light control elements L1: L11, L21, and L31 and any one of the sensor electrode SE and the dummy electrode DSE may limit the radiation angle of light emitted from the first light emitting elements EL1: EL11, EL21, and EL31 together with the first light control elements L1: L11, L21, and L31 to within the cut-off angle in the second direction Y, and may block leakage light and reflected light to prevent light leakage. The end of the black matrix BM adjacent to or overlapped with the second light control elements L2: L12, L22, and L32 and any one of the sensor electrode SE and the dummy electrode DSE may limit the radiation angle of light emitted from the second light emitting elements EL2: EL12, EL22, and EL32 together with the second light control elements L2: L12, L22, and L32 to within the cut-off angle in the first and second directions X and Y, and may block leakage light and reflected light to prevent light leakage.

The sensor electrode SE, the dummy electrode DSE, the bridge electrode BE, and the black matrix BM of the touch sensor array may be disposed in a non-emission area to serve as a barrier that blocks light.

In an embodiment, ends of the sensor electrode SE and the dummy electrode DSE may not overlap a portion of the first light control elements L1: L11, L21, and L31 which is parallel to and adjacent to the first light emitting elements EL1: EL11, EL21, and EL31 in the first direction X. Accordingly, the ends of the sensor electrode SE and the dummy electrode DSE do not limit the radiation angle of the light emitted from the first light emitting elements EL1: EL11, EL21, and EL31 so that the first light control elements L1: L11, L21, and L31 may secure wide viewing angle characteristics. A first overlapping portion in which an end portion of any one of the sensor electrode SE and the dummy electrode DSE overlaps an end portion of the first light control element L1 in the second direction Y may be spaced apart from an end portion of a light emission area of the first light emitting element EL1 in the second direction Y. A second overlapping portion in which an end portion of the black matrix BM overlaps an end portion of the first light control element L1 in the second direction Y may be spaced apart from the end portion of the light emission area of the first light emitting element EL1 in the second direction Y. An area of the first overlapping portion may be larger or smaller than an area of the second overlapping portion. A length in the first direction X of the first overlapping portion may be larger than a length in the first direction X of the first light emitting element EL1. A third overlapping portion in which an end of any one of the sensor electrode SE and the dummy electrode DSE overlaps an end of the second light control clement L2 may be spaced apart from an end of a light emission area of the first light emitting element EL1. A fourth overlapping portion, in which the end of the black matrix BM overlaps an end of the second light control element L2, may be spaced apart from an end of a light emission area of the second light emitting element EL2. An area of the third overlapping portion may be larger or smaller than an area of the fourth overlapping portion.

In the display panel 100 according to an embodiment, by arranging a plurality of contact parts CNTs of the touch sensor array in the non-emission area of the first type subpixel SP1 having the relatively smallest area of the emission area, it is possible to sufficiently secure the emission area of the second and third type subpixels SP2 and SP3 and the areas of the light control elements L1 and L2 to improve luminance.

A plurality of contact parts CNT may be disposed in the non-emission area between the second light emitting elements EL12 of the first type subpixel SP1 adjacent to each other in the second direction Y. Any one contact part CNT may be disposed in the non-emission area between the first light emitting elements EL21 of the second type subpixel SP2 adjacent to each other in the first direction X. Any one contact part CNT may be disposed in the non-emission area between the first light emitting elements EL31 of the third type subpixel SP3 adjacent to each other in the first direction X.

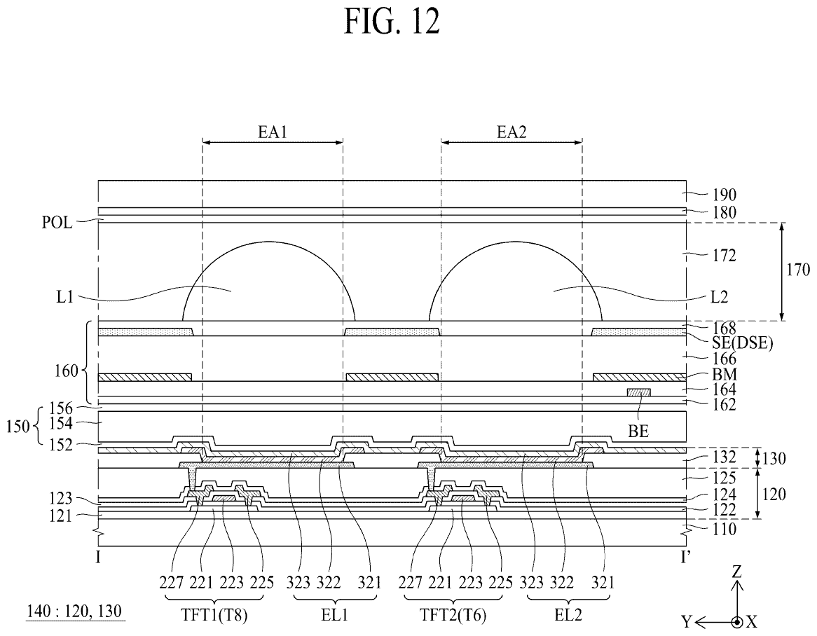

FIG. 12 is a cross-sectional view illustrating an example of a structure of a subpixel area taken along a line I-I′ in a pixel area illustrated in FIG. 11.

Referring to FIG. 12, the display panel 100 according to an embodiment may include a pixel array 140 including a circuit element layer 120 disposed on the substrate 110 and a light emitting clement layer 130 disposed on the circuit element layer 120, an encapsulation layer 150 disposed on the pixel array 140 to seal the light emitting element layer 130, a touch sensor array 160 disposed on the encapsulation layer 150, and a light control array 170 disposed on the touch sensor array 160. The display panel 100 may further include a polarizing plate POL disposed on the light control array 170, an optical transparent adhesive OCA 180, a cover substrate 190, and the like.

A cross-sectional structure of the second type subpixel SP2 among the first to third type subpixels SP1, SP2, and SP3 in the display panel 100 according to an embodiment will be described as an example with reference to FIG. 12. The first to third type subpixels SP1, SP2, and SP3 may have the same cross-sectional structure.

Each subpixel SP may include the first and second transistors TFT1 and TFT2 of the pixel circuit 10, the first light emitting element EL1 connected to the first transistor TFT1, the second light emitting element EL2 connected to the second transistor TFT2, the first light control clement L1 overlapping the light emission area EA1 on the first light emitting element EL1, and the second light control element L2 overlapping the light emission area EA2 on the second light emitting element EL2. The first transistor TFT1 may correspond to the eighth switching transistor T8 shown in FIG. 6, and the second transistor TFT2 may correspond to the sixth switching transistor T6.

The circuit element layer 120 according to an embodiment may include a plurality of insulating layers stacked on the substrate 110. For example, a plurality of insulating layers may include a buffer layer 121, a gate insulating layer 122, an interlayer insulating layer 123, a protective layer 124, and a planarization layer 125.

The substrate 110 may include an insulating material such as glass or plastic. The plastic substrate may be formed of a flexible material. For example, the substrate 110 may include at least one organic insulating material among an acrylic resin, an epoxy resin, a siloxane resin, a polyimide resin, and a polyamide resin.

The buffer layer 121 may have a single layer or multilayer structure including an inorganic insulating material such as silicon oxide (SiOx), silicon nitride (SiNx), and aluminum oxide (Al₂O₃). The buffer layer 121 may prevent an impurity such as hydrogen from being introduced into the semiconductor layer 221 through the substrate 110.

A plurality of transistors including switching transistors T8 and T6 may be disposed on the buffer layer 121.

In an embodiment, the buffer layer 121 may include a multi-buffer layer and an active buffer layer. In this case, a multi-buffer layer may be disposed on the substrate 110 and an active buffer layer may be disposed on the multi-buffer layer. A light blocking layer may be disposed between the multi-buffer layer and the active buffer layer.

Each of the transistors TFT1 and TFT2 includes a semiconductor layer 221, a gate electrode 223, a source electrode 225 and a drain electrode 227 disposed on the buffer layer 121. The gate insulating layer 122 is disposed between the semiconductor layer 221 and the gate electrode 223. The interlayer insulating layer 123 is disposed between the gate electrode 223 and the source and drain electrodes 225 and 227. The source electrode 225 and the drain electrode 227 of each of the transistors TFT1 and TFT2 may be connected to the source region and the drain region of the semiconductor layer 221, respectively, through contact holes penetrating the interlayer insulating layer 123 and the gate insulating layer 122.

The semiconductor layer 221 may include polycrystalline silicon, or may include an oxide semiconductor material. The semiconductor layer 221 may include low-temperature polysilicon (LTPS). The semiconductor layer 221 may include at least one oxide semiconductor material among an IZO (InZnO)-based, an IGO (InGaO)-based, an ITO (InSnO)-based, an IGZO (InGaZnO)-based, an IGZTO (InGaZnSnO)-based, a GZTO (GaZnSnO)-based, a GZO (GaZnO)-based, and an ITZO (InSnZnO)-based. A light shielding layer (not shown) may be further disposed under the semiconductor layer 221.

The gate insulating layer 122 may include an inorganic insulating material such as silicon oxide (SiOx) and silicon nitride (SiNx). The gate insulating layer 122 may include a material having a high dielectric constant. For example, the gate insulating layer 122 may include a High-K material such as hafnium oxide (HfO). The gate insulating layer 122 may have a multilayer structure.

The gate electrode 223 and the gate line may be disposed on the gate insulating layer 122.

The interlayer insulating layer 123 may include an inorganic insulating material such as silicon oxide (SiOx) and silicon nitride (SiNx). The interlayer insulating layer 123 may have a multilayer structure.

A source electrode 225 and a drain electrode 227, a data line, and a power line may be disposed on the interlayer insulating layer 123.

The protection layer 124 and the planarization layer 125 may be stacked on the transistors TFT1 and TFT2. The protection layer 124 may include an inorganic insulating material such as silicon oxide (SiOx) and silicon nitride (SiNx). The planarization layer 125 may include an organic insulating material different from that of the protection layer 124 and may provide a flat surface. The planarization layer 125 may have a double layer structure.

A light emitting element layer 130 including light emitting elements EL1 and EL2 may be disposed on the planarization layer 125.

Each of the first and second light emitting elements EL1 and EL2 may include an anode electrode 321 disposed on the planarization layer 125, a light emitting layer 322 disposed on the anode electrode 321, and a common cathode electrode 323 disposed on the light emitting layer 322.

The anode electrode 321 of the first light emitting element EL1 may be connected to any one of the source electrode 225 and the drain electrode 227 of the transistor TFT1 through a contact hole penetrating the planarization layer 125 and the protective layer 124. The anode electrode 321 of the second light emitting element EL2 may be connected to any one of the source electrode 225 and the drain electrode 227 of the transistor TFT2 through a contact hole penetrating the planarization layer 125 and the protective layer 124.

The anode electrode 321 may include a conductive material having a high reflectivity. The anode electrode 321 may include a metal such as aluminum (Al), silver (Ag), titanium (Ti), and a silver-palladium-copper (APC) alloy. The anode electrode 321 may further include a transparent conductive material such as an indium tin oxide (ITO) or an indium zinc oxide (IZO). In an embodiment, the anode electrode 321 may have a multilayer structure (Ti/Al/Ti) of titanium (Ti) and aluminum (Al), a multilayer structure (ITO/A;/ITO) of ITO and aluminum (Al), or a multilayer structure (ITO/APC/ITO) of ITO and APC.

The light emitting layer 322 may include an emission material layer (EML) including a light emitting material. The light emitting material may include an organic material, an inorganic material, or a hybrid material. The light emitting layer 322 may have a multilayer structure. In an embodiment, the light emitting layer 322 may further include at least one of a hole injection layer (HIL), a hole transport layer (HTL), an electron transport layer (ETL), and an electron injection layer (EIL).

The cathode electrode 323 may be a common electrode and may include a conductive material that transmits light. The cathode electrode 323 may include a transparent conductive material such as ITO or IZO. The cathode electrode 323 may include aluminum (Al), magnesium (Mg), silver (Ag), or an alloy thereof and may have a thin thickness capable of transmitting light.

The bank insulating layer 132 may be positioned on the anode electrode 321 of the first and second light emitting elements EL1 and EL2. The anode electrodes 321 of the first and second light emitting elements EL1 and EL2 are spaced apart from each other, and the bank insulating layer 132 may be positioned between the anode electrodes 321 of the first and second light emitting elements EL1 and EL2. The bank insulating layer 132 may cover the edge of the anode electrode 321. The bank insulating layer 132 may include an organic insulating material. The bank insulating layer 132 may include an organic material different from that of the planarization layer 125, and may have a single layer or a double layer structure. A spacer may be further disposed on the bank insulating layer 132.

The bank insulating layer 132 may include a plurality of open parts through which the anode electrodes 321 of the first and second light emitting elements EL1 and EL2 are exposed to define a plurality of light emission areas EA1 and EA2. The light emitting layer 322 and the cathode electrode 323 of the first and second light emitting elements EL1 and EL2 may be stacked on the anode electrode 321 exposed by the open part of the bank insulating layer 132.

The encapsulation layer 150 may be positioned on the light emitting element layer 130 including the first and second light emitting elements EL1 and EL2. The encapsulation layer 150 may prevent damage to the light emitting elements EL1 and EL2 due to external moisture and impact. The encapsulation layer 150 may have a multilayer structure. In an embodiment, the encapsulation layer 150 may include a first encapsulation layer 152, a second encapsulation layer 154, and a third encapsulation layer 156 that are sequentially stacked, but is not limited thereto. The first encapsulation layer 152, the second encapsulation layer 154, and the third encapsulation layer 156 may include an insulating material. The second encapsulation layer 154 may include a material different from that of the first encapsulation layer 152 and the third encapsulation layer 156. For example, the first encapsulation layer 152 and the third encapsulation layer 156 are inorganic encapsulation layers including an inorganic insulating material, and the second encapsulation layer 154 may include an organic encapsulation layer including an organic insulating material. Accordingly, the light emitting elements EL1 and EL2 of the display apparatus may be more effectively prevented from being damaged by external moisture and impact.

The touch sensor array 160 may include a first touch insulating layer 162 disposed on the encapsulation layer 150, a bridge electrode BE disposed on the first touch insulating layer 162, a second touch insulating layer 164 covering the bridge electrode BE, a black matrix BM disposed on the second touch insulating layer 164, a third touch insulating layer 166 covering the black matrix BM, a dummy electrode DSE and a sensor electrode SE disposed on the third touch insulating layer 166, and a fourth touch insulating layer 168 covering the sensor electrode SE and the dummy electrode DSE. The bridge electrode BE, the black matrix BM, the sensor electrode SE, and the dummy electrode DSE may be disposed in a non-emission area overlapping the bank insulating layer 132.

The ends of at least one of the sensor electrode SE, the dummy electrode DSE, and the black matrix BM may overlap the ends of the first and second light control elements L1 and L2 in the non-emission area.

The light control array 170 may include light control elements L1 and L2 disposed on the touch sensor array 160 and a protective layer 172 covering the light control elements L1 and L2.

The first light control element L1 is disposed on the light emission area EA1 of the first light emitting element EL1, and the second light control element L2 is disposed on the light emission area EA2 of the second light emitting element EL2 to control a path of light generated in the light emission areas EA1 and EA2.

The first light control element L1 may control the path of light generated in the light emission area EA1 of the first light emitting element EL1 to be a wide viewing angle in the first direction X and to be narrow angle in the second direction Y. The second light control element L2 may control the path of light generated in the light emission area EA2 of the second light emitting clement EL22 to be a narrow viewing angle in the first and second directions X and Y.

The protective layer 172 covering the light control elements L1 and L2 may include an organic insulating material. The refractive index of the protective layer 172 may be less than that of the light control elements L1 and L2. Accordingly, the light passing through the light control elements L1 and L2 may not be reflected toward the substrate 110 due to the difference in refractive index from the protective layer 172.

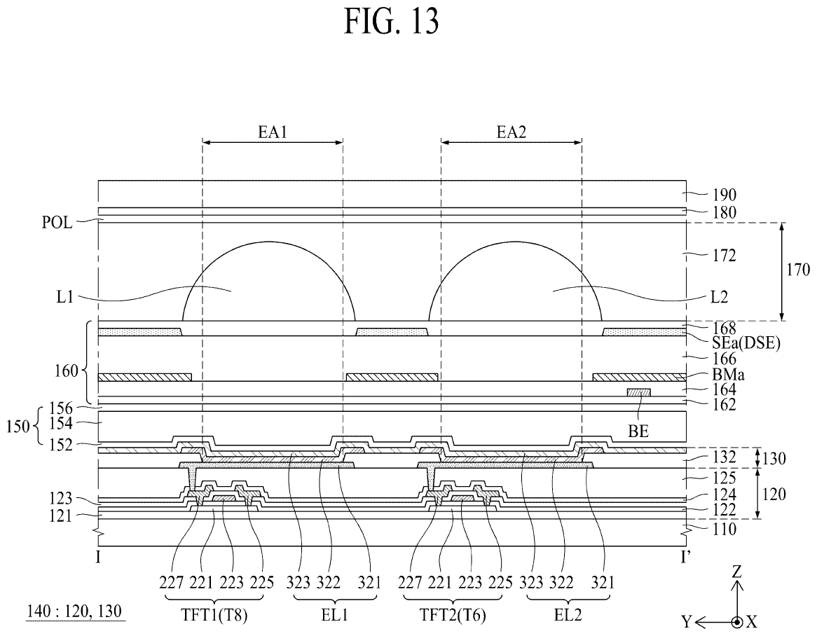

FIG. 13 is a cross-sectional view illustrating an example of another structure of a subpixel area according to an embodiment of the present disclosure.

In FIG. 13, compared to FIG. 12, the other components are the same except that the width of the black matrix BMa is greater than the widths of the sensor electrode SEa and the dummy electrode DSE, and thus the description of the same components will be omitted.

Referring to FIGS. 12 and 13, in the touch sensor array 160, the widths of the black matrices BM and BMa may be less than or greater than the widths of each of the sensor electrodes SE and SEa and the dummy electrode DSE. The sizes of the open part of the black matrices BM and BMa may be greater than or equal to the size of the open part of any one of the sensor electrodes SE and SEa and the dummy electrodes DSE. The overlapping areas of the black matrices BM and BMa and the light control elements L1 and L2 may be less than or greater than the overlapping areas of the sensor electrodes SE and SEa, the dummy electrodes DSE, and the light control elements L1 and L2.

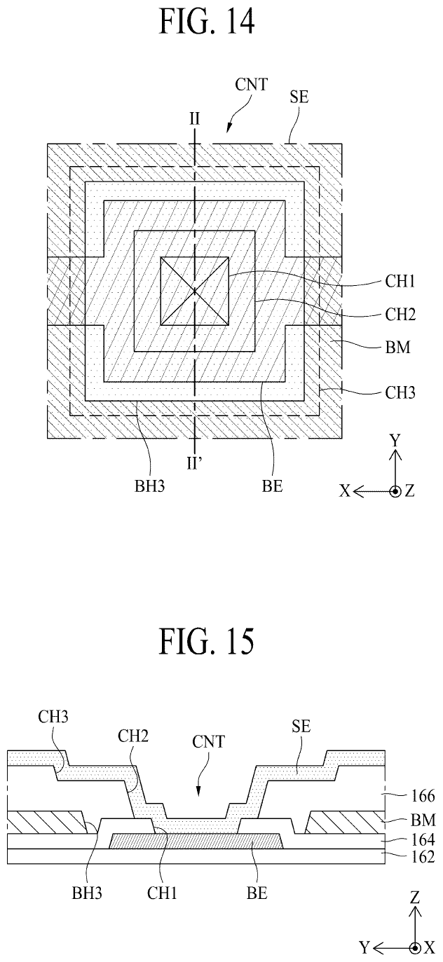

FIG. 14 is an enlarged plan view illustrating an example of a structure of a contact part in a pixel area illustrated in FIG. 11, and FIG. 15 is a cross-sectional view illustrating an example of a structure of a contact part taken along a line II-II′ shown in FIG. 14.

Referring to FIGS. 14 and 15, in the contact part CNT, the sensor electrode SE may be electrically connected to the bridge electrode BE through contact holes CH1, CH2, and CH3 of the touch insulating layer 164 and 166.

A bridge electrode BE may be disposed on the first touch insulating layer 162.

A second touch insulating layer 164 having a first contact hole CH1 exposing the bridge electrode BE may be disposed on the first touch insulating layer 162 on which the bridge electrode BE is disposed.

The black matrix BM having an open part BH3 greater than the first contact hole CH1 may be disposed on the second touch insulating layer 164. The size of the open part BH3 of the black matrix BM in the contact part CNT may be greater than the size of the bridge electrode BE. The width of the open part BH3 of the black matrix BM in the second direction Y may be greater than the width of the bridge electrode BE.

A third touch insulating layer 166 having second and third contact holes CH2 and CH3 may be disposed on the second touch insulating layer 164 on which the black matrix BM is disposed. The size of the third contact hole CH3 may be larger than the size of the second contact hole CH2. The second and third contact holes CH2 and CH3 having different sizes of the third touch insulating layer 166 may be formed using a halftone mask process.

The sensor electrode SE is disposed on the third touch insulating layer 166, and may be connected to the bridge electrode BE through the contact holes CH1, CH2, and CH3. The sensor electrode SE may be disposed in a gentle step form through contact holes CH1, CH2, and CH3 having different sizes, and may be disposed in a gentle step form even in a relatively thick third touch insulating layer 166, thereby preventing disconnection of the sensor electrode SE.

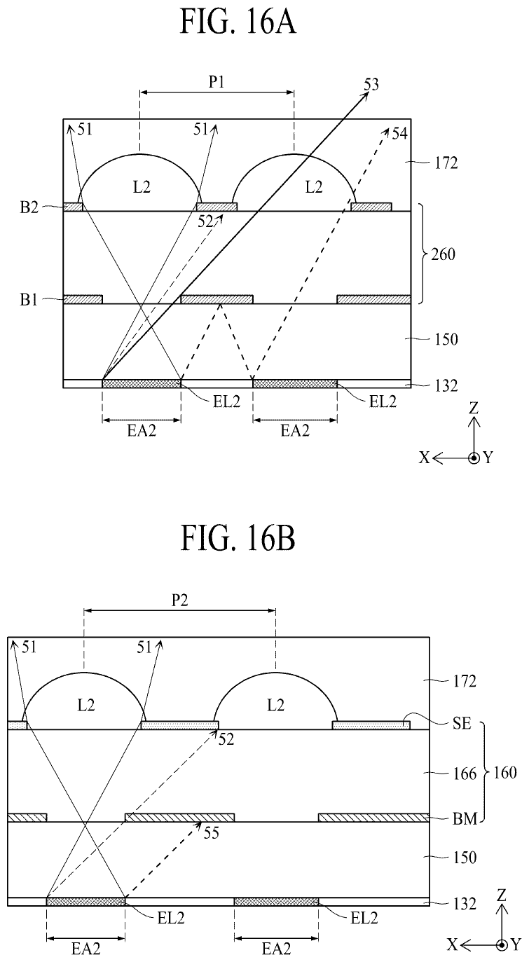

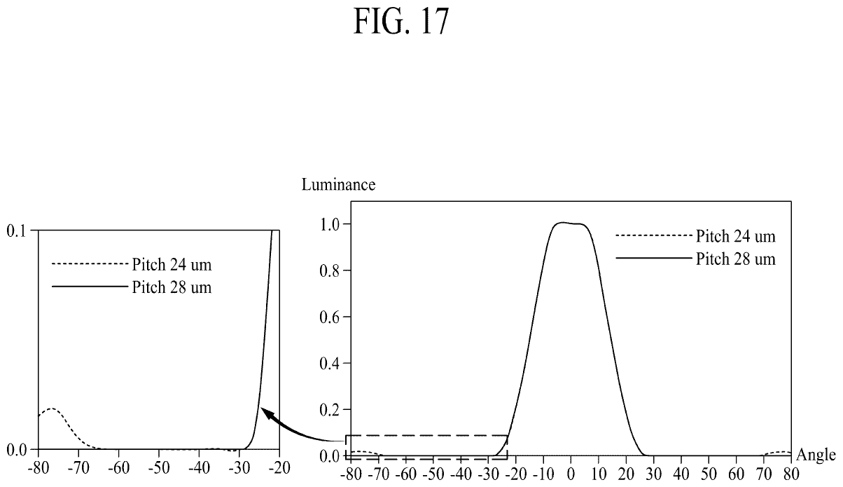

FIGS. 16A and 16B are diagrams comparing light progression paths in a subpixel area of a display panel according to a comparative example and an embodiment of the present disclosure, and FIG. 17 is a graph illustrating a light leakage reduction effect of a display apparatus according to an embodiment of the present disclosure as compared to a comparative example.

Referring to FIG. 16A, in the display panel according to the comparative example, the touch sensor array 260 may include first and second barriers B and B2 overlapping the end portion of the light control element L2. The first barrier B1 may be a sensor electrode, and the second barrier B2 may be a black matrix. The pitch between the light emitting elements EL2 of the adjacent subpixel may have a first pitch 24 μm. The size of the open part of the first barrier B1 overlapping the light control element L2 may be smaller than the size of the open part of the second barrier B2 overlapping the light control element L2.

Referring to FIGS. 16A and 17, the light 51 radiated from the light emission area EA2 of the light emitting clement EL2 in the display panel according to the comparative example and traveling along the first optical path may be limited to within the cut-off angle (±30°) by the barriers B1 and B2 and the light control element L1, and the leakage light 52 of the second optical path having a relatively small radiation angle may be blocked by the second barrier B2. However, the leakage light 53 of the third optical path having a relatively large radiation angle may occur due to insufficient first pitch 24 μm between the light emitting elements EL2 of the adjacent subpixels, and the reflected light 54 of the fourth optical path reflected by the second barrier B2 and the adjacent light emitting element EL2 may occur, indicating that light leakage occurs at a viewing angle (±65° to 80°) greater than the cut-off angle (±30°).

On the other hand, referring to FIG. 16B, in the display panel according to an embodiment, the touch sensor array 160 may include a black matrix BM and a sensor electrode SE or a dummy electrode DSE overlapping an end of the light control element L2. The black matrix BM may include a black resin material to block reflected light, and a pitch between the light emitting elements EL2 of adjacent subpixels may secure a second pitch, for example, 28 μm greater than the first pitch 24 μm. A size of an open part of the black matrix BM overlapping the light control clement L2 may be smaller or greater than that of an open part of the sensor electrode SE or the dummy electrode DSE overlapping the light control element L2.

Referring to FIGS. 16B and 17, the light 51 radiated from the light emission area EA2 of the light emitting element EL2 in the display panel according to an embodiment and traveling along the first optical path may be limited to within the cut-off angle (±30°) by the barriers B1 and B2 and the light control element L1. The leakage light 52 of the second optical path having a large radiation angle due to the sufficient second pitch 28 μm between the light emitting elements EL2 of adjacent subpixels may be blocked by the sensor electrode SE or the dummy electrode DSE, the leakage light 53 of the third optical path having a large radiation angle may also be blocked by the black matrix BM, and the light traveling along the fourth optical path is reflected by the black matrix BM, indicating that light leakage is blocked at a viewing angle larger than the cut-off angle (±30°).

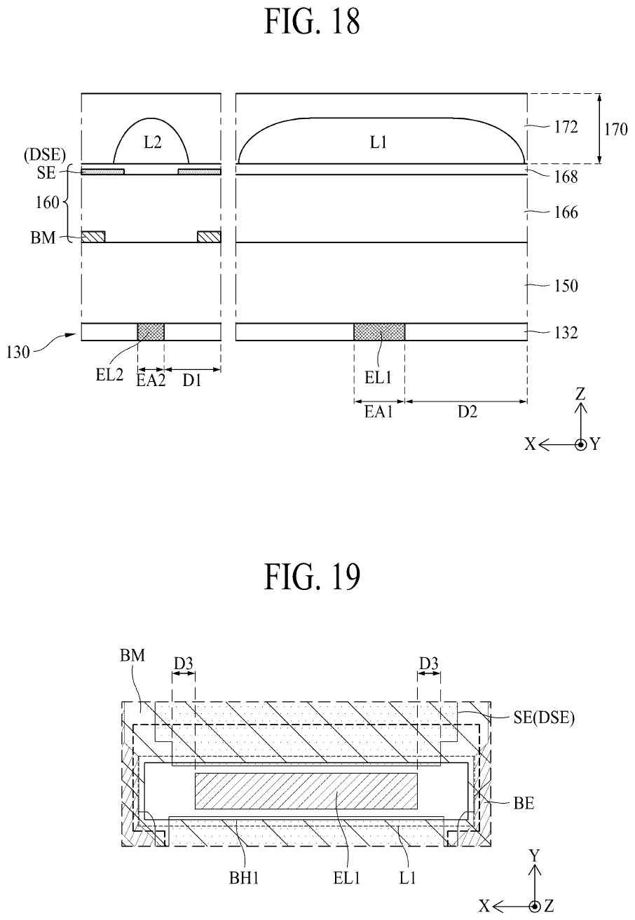

FIGS. 18 and 19 are cross-sectional views schematically illustrating a structure of a subpixel of a display panel according to an embodiment of the present disclosure.

Referring to FIGS. 18 and 19, a subpixel according to an embodiment may include a light emitting clement layer 130 including light emitting elements EL1 and EL2, an encapsulation layer 150 disposed on the light emitting element layer 130, a touch sensor array 160 including a black matrix BM, a sensor electrode SE and a dummy electrode DSE stacked on the encapsulation layer 150, and a light control array 170 including light control elements L1 and L2 disposed on the touch sensor array 160.

Referring to FIG. 18, in order to improve light efficiency, the second light control clement L2 may have a light incident surface larger than the size of the light emission area EA2 so as to overlap the light emission area EA2 of the second light emitting clement EL2 and overlap the non-emission area surrounding the light emission area EA2. In order to block light leakage, the size of open part of the black matrix BM disposed in the non-emission area may be larger or smaller than the size of the light incident surface of the second light control element L2, and the end of the black matrix BM may not overlap or overlap the end of the second light control element L2. In order to block light leakage, the size of the open part of the sensor electrode SE or the dummy electrode DSE disposed in the non-emission area may be smaller than the size of the light incident surface of the second light control element L2, and the end of the sensor electrode SE or the dummy electrode DSE may overlap the end of the second light control element L2. Accordingly, the second light control element L2 may limit the cut-off angle with respect to the first and second directions X and Y of the light emitted from the second light emitting element EL2 to within a specific value, thereby securing the narrow viewing angle characteristic in the second direction Y.

In the second type subpixel SP2 (refer to FIG. 11) according to an embodiment, a distance D1 in the first direction X between an end portion of the sensor electrode SE disposed in the non-emission area and an end portion of the bank insulating layer 132 determining the emission area EA2 of the second light emitting element EL2 may be set to be about 16 μm. Accordingly, the sensor electrode SE may block light leakage from the second light emitting element EL2 and may secure an area of the sensor electrode SE in the non-emission area to improve touch sensing sensitivity.

Referring to FIGS. 18 and 19, in order to improve light efficiency, the first light control element L1 may have a light incident surface larger than the size of the light emission area EA1 so as to overlap the light emission area EA1 of the first light emitting element EL1 and overlap the non-emission area surrounding the light emission area EA1. In order to secure a wide viewing angle characteristic in the first direction X, the first light control element L1 may not overlap the black matrix BM, the sensor electrode SE, or the dummy electrode DSE in the non-emission area of the first direction X.

In an embodiment, the distance D2 in the first direction X between the end portion of the first light control element L1 and the end portion of the bank insulating layer 132 that determines the light emission area EA1 of the first light emitting element EL1 may be set to about 15 μm. Accordingly, the first light control element L1 may not only block light leakage from the second light emitting element EL2 but also increase the cut-off angle in the first direction X to secure the wide viewing angle characteristic in the first direction X.

Referring to FIG. 19, in one embodiment, the length in the first direction X between the ends of the sensor electrode SE or the dummy electrode DSE overlapping the end of the first light control element L1 in the second direction Y may be longer than a length of the light emission area of the first light emitting element EL1 in the first direction. In one embodiment, the distance D3 in the first direction X between the end of the sensor electrode SE or the dummy electrode DSE overlapping the end of the first light control element L1 in the second direction Y and the end of the light emission area (the end of the bank insulating layer) may be set to about 5 μm. Accordingly, it is possible to block the diagonal light leakage caused by the light emitted from the first light emitting element EL1 traveling in the diagonal direction, and to improve touch sensing sensitivity by securing the area of the sensor electrode SE or the dummy electrode DSE as much as possible in the non-emission area.

In an embodiment, a distance in the second direction Y between an end portion of the first light control element L1 in the second direction Y and an end portion of the sensor electrode SE or the dummy electrode DSE in the second direction Y may be set to be about 2 μm. Accordingly, the first light control element L1 may limit the cut-off angle with respect to the second direction Y of the light emitted from the first light emitting element EL1 to within a specific value to secure the narrow viewing angle characteristic in the second direction Y.

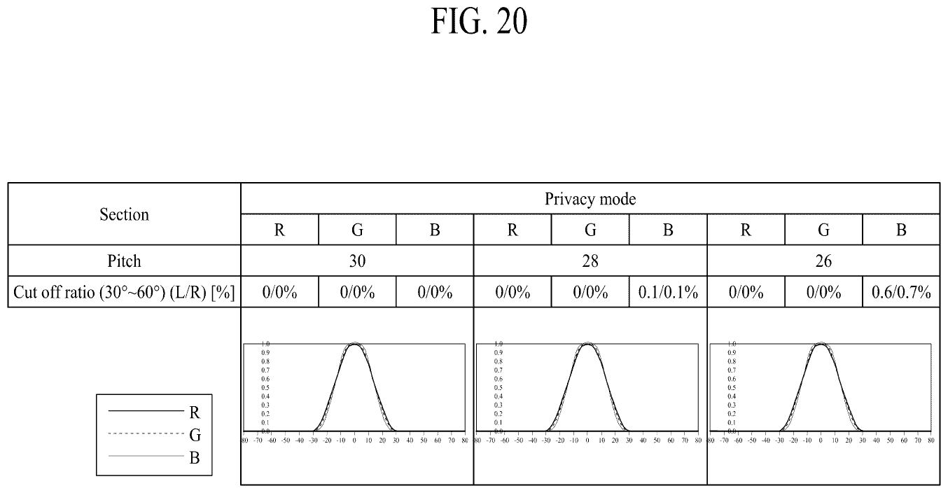

FIG. 20 is graphs illustrating a viewing angle cut-off ratio enhancement effect of a display apparatus according to an embodiment of the present disclosure.

Referring to FIG. 20, in the display apparatus according to an embodiment, when the pitch between the second light emitting elements of the adjacent subpixel emitting light in the privacy mode is less than or equal to 26 μm, the cut-off ratio of the red light R and the blue light B in the cut-off angle (30 degrees˜60 degrees) in the first direction (X, L/R) may block light leakage at 0%, while the cut-off ratio of the green light G may be 0.6% to 0.7%, indicating that a weak light leakage may occur.

In an embodiment, when the pitch between the second light emitting elements of the adjacent subpixel emitting light in the privacy mode is 28 μm or more, it may be seen that the cut-off ratio of the red light R, the green light G, and the blue light B in the cut-off angle (30° to 60°) in the first direction (X, L/R) may block light leakage to 0%.

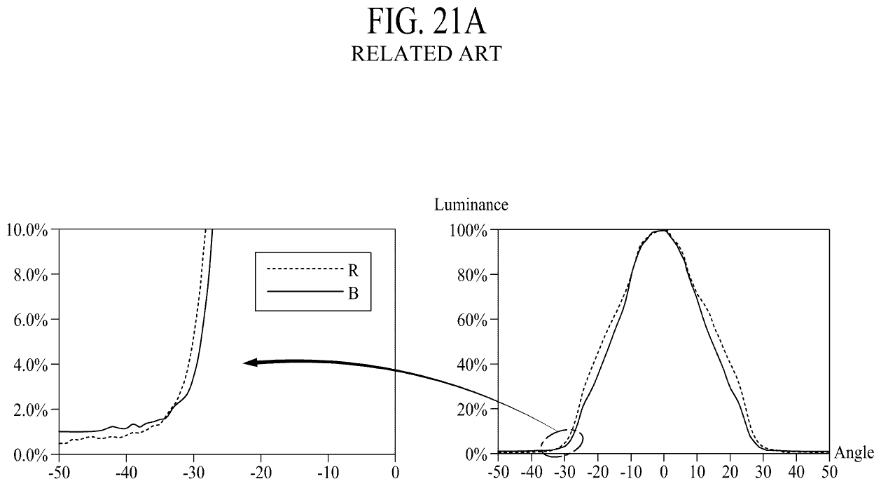

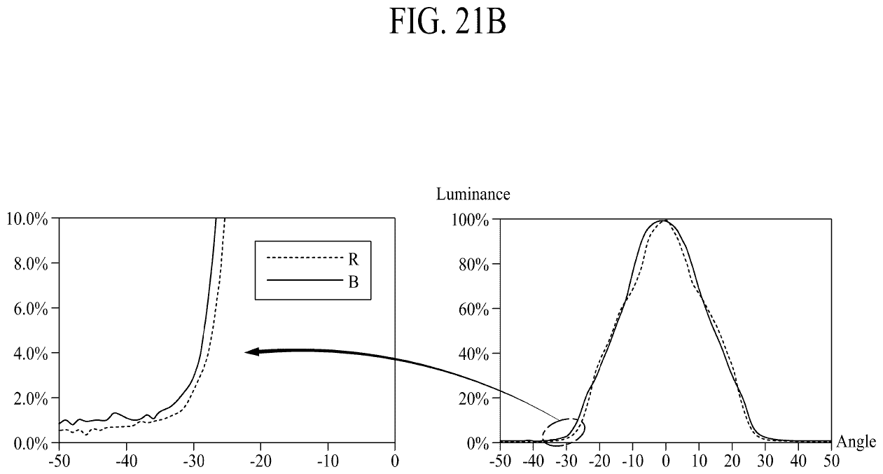

FIGS. 21A and 21B are graphs illustrating a color difference reduction effect of a display apparatus according to an embodiment compared to a comparative example.

In the display apparatus according to a comparative example and an embodiment, the light control elements L1 and L2 may have a refractive index difference according to light wavelengths. For example, in the first and second lenses which are the light control elements L1 and L2, the refractive index of the blue light B having the center wavelength of 450 nm may be 1.68, the refractive index of the green light G having the center wavelength of 550 nm may be 1.65, and the refractive index of the red light R having the center wavelength of 650 nm may be 1.63.

Referring to FIG. 21A, as the first light emitting elements and the second light emitting elements of red, green, and blue subpixels have the same light emission area regardless of color in the display apparatus according to the comparative example, the luminance reduction rate of the blue light B increases compared to the luminance reduction rate of the red light R near the cut-off angle (30°) of the viewing angle, resulting in a color difference such as yellowish.

On the other hand, referring to FIG. 21B, in the display apparatus according to an embodiment, the first light emitting elements (see EL11, EL21, EL31, of FIG. 10) and the second light emitting elements (see EL12, EL22, EL32 of FIG. 10) of red, green, and blue subpixels may have different light emission areas for each color. In an embodiment, the size of the light emission area may increase in the order of red, green, and blue subpixels in the same order as in the order of the refractive index of the red/green/blue light R/G/B of the lens, which is the light control elements L1 and L2. Accordingly, it may be seen that the luminance reduction rate of the blue light B is reduced than the luminance reduction rate of the red light R near the cut-off angle 30°, thereby minimizing the color difference such as yellowish, and thus, display performance such as display quality may be improved.

Accordingly, the present disclosure may have the following advantages.

According to an embodiment of the present disclosure, the display apparatus according to an embodiment may not only control the viewing angle according to the needs of the user by separately driving the light emitting elements of each subpixel, but also appropriately arranging the black matrix, sensor electrodes, and dummy electrodes serving as light barriers in the touch sensor array so as to overlap and non-overlap the light control element in the non-emission area to secure the narrow-view angle characteristics and the wide-view angle characteristics according to the viewing angle control, and may improve display performance such as luminance and display quality by blocking light leakage caused by leakage light and reflected light.

According to an embodiment of the present disclosure, the display apparatus according to an embodiment may improve touch sensing sensitivity by securing as much area of the sensor electrode and the dummy electrode disposed in the non-emission area in the touch sensor array, thereby improving touch sensing performance.

According to an embodiment of the present disclosure, the display apparatus according to an embodiment may improve display performance such as display quality by differentiating the size of the emission area for each wavelength and minimizing a color difference such as yellowish in the vicinity of the cut-off angle of the viewing angle due to the difference in refractive index for each wavelength of the light control element.

According to an embodiment of the present disclosure, the display apparatus according to an embodiment may also achieve a low power consumption effect by improving touch sensing performance and display performance.

A display apparatus according to some aspects may include a pixel array including a pixel circuit and a plurality of subpixels including a first light emitting element and a second light emitting element connected to the pixel circuit; an encapsulation layer disposed on the pixel array to seal a light emitting clement layer including the first light emitting element and second light emitting clement; a touch sensor array including a black matrix, a sensor electrode and a dummy electrode disposed on the encapsulation layer and overlapping the non-emission area of the pixel array; and a light control array including a first light control element overlapping the first light emitting element and a second light control clement overlapping the second light emitting clement disposed on the touch sensor array, wherein the sensor electrode may be disposed in a non-emission area of a first type subpixel among the plurality of subpixels, and the dummy electrode may be disposed in a non-emission area of a second type subpixel and a third type subpixel among the plurality of subpixels.

In the display apparatus according to some aspects, the pixel array may include a first column line and a second column line adjacent to each other in a first direction, wherein the first column line may include a plurality of the first type subpixels arranged along a second direction different from the first direction, the second column line may include a plurality of the second type subpixels and the third type subpixels in which the second type subpixels and the third type subpixels are alternately arranged along the second direction, the first type subpixel may be disposed adjacent to the second type subpixel and third type subpixel in the first direction, the second type subpixel and third type subpixel may be disposed adjacent to each other in the second direction, and the first to third types of subpixels emit light of different colors, respectively.

In the display apparatus according to some aspects, the first type subpixel may include a 1-1 light emitting element having a 1-1 light emission area having a structure longer in the first direction than the second direction, and a plurality of 1-2 light emitting elements having a size smaller than that of the 1-1 light emission area and a plurality of 1-2 light emission areas separated in the second direction with the 1-1 light emitting element interposed therebetween, wherein the plurality of 1-2 light emitting elements may share an anode electrode connected to the pixel circuit of the first type subpixel.

In the display apparatus according to some aspects, the second type subpixel may include a 2-1 light emitting element having a 2-1 light emission area having a structure longer in the first direction than the second direction, and a plurality of 2-2 light emitting elements having a size smaller than that of the 2-1 light emission area and a plurality of 2-2 light emission areas spaced apart from the 2-1 light emitting element in the second direction, wherein the plurality of 2-2 light emitting elements may be disposed in parallel in the first direction, and the plurality of 2-2 light emitting elements may share an anode electrode connected to a pixel circuit of the second type subpixel.

In the display apparatus according to some aspects, the third type subpixel may include a 3-1 light emitting element having a 3-1 light emission area having a structure longer in the first direction than the second direction, and a plurality of 3-2 light emitting elements having a size smaller than that of the 3-1 light emission area and a plurality of 3-2 light emission areas spaced apart from the 3-1 light emitting clement in the second direction, wherein the plurality of 3-2 light emitting elements may be disposed in parallel in the first direction, and be disposed adjacent to the plurality of 2-2 light emitting elements in the second direction, and the plurality of 3-2 light emitting element may share an anode electrode connected to a pixel circuit of the third type subpixel.

In the display apparatus according to some aspects, the light control array may include a 1-1 light control element, a 2-1 light control element and a 3-1 light control element individually overlapping the 1-1 light emitting clement, the 2-1 light emitting element, and the 3-1 light emitting element, and a plurality of 1-2 light control elements, a plurality of 2-2 light control elements and a plurality of 3-2 light control elements individually overlapping a plurality of 1-2 light emitting elements, a plurality of 2-2 light emitting elements, and a plurality of 3-2 light emitting elements, wherein a size of a light incident surface of each of the 1-1 light control element, the 2-1 light control element, and the 3-1 light control element may be larger than a size of a light incident surface of each of the 1-2 light control elements, the 2-2 light control element, and the 3-2 light control element.

In the display apparatus according to some aspects, the 1-1 light emitting element, the 2-1 light emitting element, and the 3-1 light emitting element may have a light emission area having different sizes for each color, the plurality of 1-2 light emitting elements, the plurality of 2-2 light emitting elements, and the plurality of 3-2 light emitting elements may have a light emission area having different sizes for each color, the 1-1 light control element, the 2-1 light control element, and the 3-1 light control element may have a light incident surface size proportional to the size of the light emission area of the 1-1 light emitting element, the 2-1 light emitting element, and the 3-1 light emitting element, and the plurality of 1-2 light control elements, the plurality of 2-2 light control elements, and the plurality of 3-2 light control elements may have a light incident surface size proportional to the size of the light emission area of the plurality of 1-2 light emitting elements, the plurality of 2-2 light emitting elements, and the plurality of 3-2 light emitting elements.

In the display apparatus according to some aspects, the touch sensor array may include a plurality of sensor electrodes arranged along the first column line, wherein each of the plurality of sensor electrodes may be separated from another sensor electrode adjacent in the second direction with the 1-1 light emitting clement interposed therebetween.

In the display apparatus according to some aspects, each of the plurality of sensor electrodes may include a first sensor electrode portion disposed in a non-emission area around the plurality of 1-2 light emitting elements of the first type subpixel, a second sensor electrode portion disposed in a non-emission area around the plurality of 2-2 light emitting elements of the second type subpixel adjacent to the first type subpixel and symmetrical to the first sensor electrode portion in the second direction, and a third sensor electrode portion connecting the first sensor electrode portion to the second sensor electrode portion.

In the display apparatus according to some aspects, the touch sensor array may further include a bridge electrode overlapping with the sensor electrode with a touch insulating layer interposed therebetween, wherein the bridge electrode may be connected to the first sensor electrode portion and the second sensor electrode portion through a plurality of contact parts, and the third sensor electrode portion may be disposed in the second direction between the plurality of contact parts.

In the display apparatus according to some aspects, each of the first sensor electrode portion and the second sensor electrode portion may include a first portion surrounding the second light emitting element, and a second portion overlapping any one of the plurality of contact parts and having an area smaller than the first portion.

In the display apparatus according to some aspects, the bridge electrode may include a first bridge electrode portion and a second bridge electrode portion extending along the first column line from both sides of the first column line to overlap the sensor electrode and the dummy electrode, and symmetrical in the first direction, and a third bridge electrode portion connecting the first bridge electrode portion to the second bridge electrode portions in each of the plurality of contact parts.

In the display apparatus according to some aspects, the first bridge electrode portion and the second bridge electrode portion extending along the first column line may have a pattern shape in which a mutual interval in the first direction varies along the second direction.

In the display apparatus according to some aspects, the first bridge electrode portion and the second bridge electrode portion extending along the first column line may overlap the dummy electrode at a maximum mutual interval in the first direction in a non-emission area adjacent to the 1-1 light control element along the first direction, and may partially overlap the sensor electrode at a minimum mutual interval in the first direction in a non-emission area disposed between the plurality of the contact parts, the 2-1 light control element and the 3-1 light control element.

In the display apparatus according to some aspects, the first bridge electrode portion and the second bridge electrode portion extending along the first column line may have an oblique pattern shape overlapping each other through the dummy electrode and the sensor electrode between the maximum mutual interval and the minimum mutual interval.

In the display apparatus according to some aspects, each of the plurality of contact parts may include the third bridge electrode portion disposed on a first touch insulating layer on the encapsulation layer, a second touch insulating layer disposed on the first touch insulating layer on which the third bridge electrode portion is disposed and having a first contact hole exposing the third bridge electrode portion, the black matrix disposed on the second touch insulating layer and having an open part larger than the first contact hole, a third touch insulating layer disposed on the second touch insulating layer on which the black matrix is disposed and provided with a second contact hole larger than the first contact hole and smaller than the open part, and a third contact hole larger than the open part, and the sensor electrode disposed on the third touch insulating layer and connected to the third bridge electrode portion through the third contact hole, the second contact hole, and the first contact hole.

In the display apparatus according to some aspects, the touch sensor array may include a plurality of dummy electrodes disposed in a non-emission area of the second column line, separated from the sensor electrodes disposed on the same layer, and electrically floated. The plurality of dummy electrodes may include a first dummy electrode disposed in a non-emission area around the plurality of 2-2 light emitting element and the plurality of 3-2 light emitting element adjacent to each other along the second direction, and a second dummy electrode disposed in a non-emission area disposed between the 3-1 light emitting element and the 2-1 light emitting element adjacent to each other along the second direction.

In the display apparatus according to some aspects, the first dummy electrode may have a pattern shape including a portion having a maximum length in the first direction in a non-emission area adjacent to the sensor electrode in the first direction and a portion having a minimum length in the first direction in a non-emission area between 1-1 light control elements adjacent in the first direction.

In the display apparatus according to some aspects, the second dummy electrode may have a pattern shape including a portion having a maximum length in the first direction in a non-emission area adjacent to the 3-1 light control element in the second direction and a portion having a minimum length in the first direction in the non-emission area adjacent to the 2-1 light control clement in the second direction.

In the display apparatus according to some aspects, the first light control element may limit a viewing angle of light emitted from the first light emitting element along with any one of the sensor electrode and the dummy electrode, and the black matrix to within a first cut-off angle in the second direction, and the second light control element may limit a viewing angle of light emitted from the second light emitting element along with any one of the sensor electrode and the dummy electrode, and the black matrix to within the first cut-off angle in the first and second directions.

In the display apparatus according to some aspects, a first overlapping portion in which an end portion of any one of the sensor electrode and the dummy electrode may overlap an end portion of the first light control element in the second direction is spaced apart from an end portion of a light emission area of the first light emitting element in the second direction, a second overlapping portion in which an end portion of the black matrix may overlap an end portion of the first light control element in the second direction is spaced apart from the end portion of the light emission area of the first light emitting element in the second direction, and an area of the first overlapping portion may be larger or smaller than an area of the second overlapping portion.

In the display apparatus according to some aspects, a first open part of any one of the sensor electrode and the dummy electrode and a second open part of the black matrix may overlap the first light emitting element and the first light control element, and a size of the first open part may be larger or smaller than a size of the second open part.

In the display apparatus according to some aspects, a length in the first direction of a first overlapping portion in which the end portion of any one of the sensor electrode and the dummy electrode overlaps the end portion of the first light control element in the second direction may be larger than a length in the first direction of the first light emitting element.

In the display apparatus according to some aspects, a third overlapping portion in which an end of any one of the sensor electrode and the dummy electrode overlaps an end of the second light control element, may be spaced apart from an end of a light emission area of the first light emitting clement, a fourth overlapping portion, in which the end of the black matrix overlaps an end of the second light control element, may be spaced apart from an end of a light emission area of the second light emitting element, and an area of the third overlapping portion may be larger or smaller than an area of the fourth overlapping portion.

In the display apparatus according to some aspects, a third open part of any one of the sensor electrode and the dummy electrode and a fourth open part of the black matrix may overlap the second light emitting element and the second light control element, and a size of the third open part may be larger or smaller than a size of the fourth open part.

In the display apparatus according to some aspects, each of the 1-1, 2-1, and 3-1 light emitting elements may be connected to a first switching transistor provided in a pixel circuit of each of the first to third types of subpixels and controlled by a first mode signal, each of the 1-2, 2-2, and 3-2 light emitting elements may be connected to a second switching transistor provided in the pixel circuit of each of the first to third types of subpixels and controlled by a second mode signal, and the first and second switching transistors may electrically connected to a driving transistor provided in a pixel circuit of each of the first to third types of subpixels.

In the display apparatus according to some aspects, among the first sensor electrode portion, the second sensor electrode portion and the third sensor electrode portion, the third sensor electrode portion may have the smallest area.

In the display apparatus according to some aspects, a width of the open part of the black matrix in the second direction may be greater than a width of the bridge electrode.

In the display apparatus according to some aspects, at least one of the sensor electrode, the dummy electrode, and the black matrix does not overlap an end portion of the first light control element.

In the display apparatus according to some aspects, a size of an open part of the black matrix may be greater than or equal to a size of an open part of any one of the sensor electrode and the dummy electrode.

In the display apparatus according to some aspects, the black matrix may comprise a first open part overlapping the first light emitting element, and a second open part overlapping the second light emitting element, wherein a size of the first open part of the black matrix is larger than a size of a light emission area of the second light emitting element, and a size of the second open part of the black matrix is larger than a size of a light emission area of the first light emitting element.

In the display apparatus according to some aspects, the size of the first open part of the black matrix may be smaller or larger than a size of a light incident surface of the second light control element, and the size of the second open part of the black matrix may be smaller or larger than a size of a light incident surface of the first light control element.

In the display apparatus according to some aspects, a width of the black matrix may be less than or greater than a width of each of the sensor electrode and the dummy electrode.

In the display apparatus according to some aspects, a pitch between the second light emitting elements of adjacent subpixels may be greater than 24 μm.

In the display apparatus according to some aspects, a distance in the second direction between an end portion of the first light control element in the second direction and an end portion of the sensor electrode or the dummy electrode in the second direction may be set to be 2 μm.

The above-described feature, structure, and effect of the present disclosure are included in at least one embodiment of the present disclosure, but are not limited to only one embodiment. Furthermore, the feature, structure, and effect described in at least one embodiment of the present disclosure may be implemented through combination or modification of other embodiments by those skilled in the art. Therefore, content associated with the combination and modification should be construed as being within the scope of the present disclosure.

It will be apparent to those skilled in the art that various substitutions, modifications, and variations are possible within the scope of the present disclosure without departing from the spirit and scope of the present disclosure. Therefore, the scope of the present disclosure is represented by the following claims, and all changes or modifications derived from the meaning, range and equivalent concept of the claims should be interpreted as being included in the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a pixel array including:
a pixel circuit; and
a plurality of subpixels including a first light emitting element and a second light emitting element electrically connected to the pixel circuit;
an encapsulation layer on the pixel array, the encapsulation layer configured to seal a light emitting element layer including the first light emitting element and the second light emitting element;
a touch sensor array including a black matrix, a sensor electrode, and a dummy electrode on the encapsulation layer, the touch sensor array overlapping a non-emission area of the pixel array; and
a light control array including a first light control element overlapping the first light emitting element and a second light control element overlapping the second light emitting element on the touch sensor array,
wherein the sensor electrode is disposed in a non-emission area of a first type subpixel among the plurality of subpixels, and
wherein the dummy electrode is disposed in a non-emission area of a second type subpixel and a third type subpixel among the plurality of subpixels.

2. The display apparatus according to claim 1,
wherein the pixel array includes:
a first column line and a second column line adjacent to each other in a first direction,
wherein the first column line includes a plurality of the first type subpixels arranged along a second direction different from the first direction,
wherein the second column line includes a plurality of the second type subpixels and the third type subpixels in which the second type subpixels and the third type subpixels are alternately arranged along the second direction,
wherein the first type subpixel is disposed adjacent to the second type subpixel and third type subpixel in the first direction,
wherein the second type subpixel and third type subpixel are disposed adjacent to each other in the second direction, and
wherein the first to third types of subpixels emit light of different colors, respectively.

3. The display apparatus according to claim 2,
wherein the first type subpixel includes:
a 1-1 light emitting element having a 1-1 light emission area having a structure longer in the first direction than the second direction; and
a plurality of 1-2 light emitting elements having a size smaller than that of the 1-1 light emission area and a plurality of 1-2 light emission areas separated in the second direction with the 1-1 light emitting element interposed therebetween,
wherein the plurality of 1-2 light emitting elements share an anode electrode electrically connected to the pixel circuit of the first type subpixel.

4. The display apparatus according to claim 3,
wherein the second type subpixel includes:
a 2-1 light emitting element having a 2-1 light emission area having a structure longer in the first direction than the second direction; and
a plurality of 2-2 light emitting elements having a size smaller than that of the 2-1 light emission area and a plurality of 2-2 light emission areas spaced apart from the 2-1 light emitting element in the second direction,
wherein the plurality of 2-2 light emitting elements is disposed in parallel in the first direction, and
wherein the plurality of 2-2 light emitting elements share an anode electrode electrically connected to a pixel circuit of the second type subpixel.

5. The display apparatus according to claim 4,
wherein the third type subpixel includes:
a 3-1 light emitting element having a 3-1 light emission area having a structure longer in the first direction than the second direction; and
a plurality of 3-2 light emitting elements having a size smaller than that of the 3-1 light emission area and a plurality of 3-2 light emission areas spaced apart from the 3-1 light emitting element in the second direction,
wherein the plurality of 3-2 light emitting elements is disposed in parallel in the first direction, and are disposed adjacent to the plurality of 2-2 light emitting elements in the second direction, and
wherein the plurality of 3-2 light emitting element share an anode electrode electrically connected to a pixel circuit of the third type subpixel.

6. The display apparatus according to claim 5,
wherein the light control array includes:
a 1-1 light control element, a 2-1 light control element and a 3-1 light control element individually overlapping the 1-1 light emitting element, the 2-1 light emitting element, and the 3-1 light emitting element,
a plurality of 1-2 light control elements, a plurality of 2-2 light control elements, a plurality of 3-2 light control elements individually overlapping the plurality of 1-2 light emitting elements, the plurality of 2-2 light emitting elements, and the plurality of 3-2 light emitting elements,
wherein a size of a light incident surface of each of the 1-1 light control element, the 2-1 light control element, and the 3-1 light control element is larger than a size of a light incident surface of each of the 1-2 light control elements, the 2-2 light control element, and the 3-2 light control element.

7. The display apparatus according to claim 6,
wherein the 1-1 light emitting element, the 2-1 light emitting element, and the 3-1 light emitting element have a light emission area having different sizes for each color,
wherein the plurality of 1-2 light emitting elements, the plurality of 2-2 light emitting elements, and the plurality of 3-2 light emitting elements have a light emission area having different sizes for each color,
wherein the 1-1 light control element, the 2-1 light control element, and the 3-1 light control element have a light incident surface size proportional to the size of the light emission area of the 1-1 light emitting element, the 2-1 light emitting element, and the 3-1 light emitting element, and
wherein the plurality of 1-2 light control elements, the plurality of 2-2 light control elements, and the plurality of 3-2 light control elements have a light incident surface size proportional to the size of the light emission area of the plurality of 1-2 light emitting elements, the plurality of 2-2 light emitting elements, and the plurality of 3-2 light emitting elements.

8. The display apparatus according to claim 6,
wherein the touch sensor array includes:
a plurality of sensor electrodes arranged along the first column line,
wherein each of the plurality of sensor electrodes is separated from another sensor electrode adjacent in the second direction with the 1-1 light emitting element interposed therebetween.

9. The display apparatus according to claim 8,
wherein each of the plurality of sensor electrodes includes:
a first sensor electrode portion disposed in a non-emission area around the plurality of 1-2-th light emitting elements of the first type subpixel;
a second sensor electrode portion disposed in a non-emission area around the plurality of 2-2 light emitting elements of the second type subpixel adjacent to the first type subpixel and symmetrical to the first sensor electrode portion in the second direction; and
a third sensor electrode portion electrically connecting the first sensor electrode portion to the second sensor electrode portion.

10. The display apparatus according to claim 9,
wherein the touch sensor array further includes,
a bridge electrode overlapping with the sensor electrode with a touch insulating layer interposed therebetween,
wherein the bridge electrode is electrically connected to the first sensor electrode portion and the second sensor electrode portion through a plurality of contact parts, and
wherein the third sensor electrode portion is disposed in the second direction between the plurality of contact parts.

11. The display apparatus according to claim 10,
wherein each of the first sensor electrode portion and the second sensor electrode portion includes:
a first portion surrounding the second light emitting element; and
a second portion overlapping any one of the plurality of contact parts and having an area smaller than the first portion.

12. The display apparatus according to claim 10,
wherein the bridge electrode includes:
a first bridge electrode portion and a second bridge electrode portion extending along the first column line from both sides of the first column line to overlap the sensor electrode and the dummy electrode, and symmetrical in the first direction; and
a third bridge electrode portion electrically connecting the first bridge electrode portion to the second bridge electrode portions in each of the plurality of contact parts.

13. The display apparatus according to claim 12,
wherein the first bridge electrode portion and the second bridge electrode portion extending along the first column line have a pattern shape in which a mutual interval in the first direction varies along the second direction.

14. The display apparatus according to claim 13,
wherein the first bridge electrode portion and the second bridge electrode portion extending along the first column line overlap the dummy electrode at a maximum mutual interval in the first direction in a non-emission area adjacent the 1-1 light control element along the first direction, and
wherein partially overlaps the sensor electrode at a minimum mutual interval in the first direction in a non-emission area disposed between the plurality of the contact parts, the 2-1 light control element and the 3-1 light control element.

15. The display apparatus according to claim 14,
wherein the first bridge electrode portion and the second bridge electrode portion extending along the first column line have an oblique pattern shape overlapping each other through the dummy electrode and the sensor electrode between the maximum mutual interval and the minimum mutual interval.

16. The display apparatus according to claim 12,
wherein each of the plurality of contact parts includes:
the third bridge electrode portion on a first touch insulating layer on the encapsulation layer;
a second touch insulating layer on the first touch insulating layer on which the third bridge electrode portion is disposed and having a first contact hole exposing the third bridge electrode;
the black matrix on the second touch insulating layer and having an open part larger than the first contact hole;
a third touch insulating layer on the second touch insulating layer on which the black matrix is disposed and provided with a second contact hole larger than the first contact hole and smaller than the open part, and a third contact hole larger than the open part; and
the sensor electrode on the third touch insulating layer and electrically connected to the third bridge electrode portion through the third contact hole, the second contact hole, and the first contact hole.

17. The display apparatus according to claim 8,
wherein the touch sensor array includes:
a plurality of dummy electrodes disposed in a non-emission area of the second column line, separated from the sensor electrodes disposed on the same layer, and electrically floated,
wherein the plurality of dummy electrodes includes:
a first dummy electrode disposed in a non-emission area around the plurality of 2-2 light emitting element and the plurality of 3-2 light emitting element adjacent to each other along the second direction; and
a second dummy electrode disposed in a non-emission area disposed between the 3-1 light emitting element and the 2-1 light emitting element adjacent to each other along the second direction.

18. The display apparatus according to claim 17,
wherein the first dummy electrode has a pattern shape including a portion having a maximum length in the first direction in a non-emission area adjacent to the sensor electrode in the first direction and a portion having a minimum length in the first direction in a non-emission area between 1-1 light control elements adjacent in the first direction.

19. The display apparatus according to claim 17,
wherein the second dummy electrode has a pattern shape including a portion having a maximum length in the first direction in a non-emission area adjacent to the 3-1 light control element in the second direction and a portion having a minimum length in the first direction in the non-emission area adjacent to the 2-1 light control element in the second direction.

20. The display apparatus according to claim 1,
wherein the first light control element limits a viewing angle of light emitted from the first light emitting element along with any one of the sensor electrode and the dummy electrode, and the black matrix to within a first cut-off angle in the second direction, and
wherein the second light control element limits a viewing angle of light emitted from the second light emitting element along with any one of the sensor electrode and the dummy electrode, and the black matrix to within the first cut-off angle in the first and second directions.
